(19) United States
(12) Patent Application Publication
(10) Pub. No.: US 2023/0211436 A1
(43) Pub. Date: Jul. 6, 2023

(54) APPARATUS FOR TREATING SUBSTRATE AND METHOD FOR TREATING A SUBSTRATE

(71) Applicant: SEMES CO., LTD., Cheonan-si (KR)

(72) Inventors: Hyo Won YANG, Seoul (KR); Hyun Yoon, Hwaseong-si (KR); Ji Hoon Jeong, Hwaseong-si (KR); Ki Hoon Choi, Cheonan-si (KR); In Ki Jung, Hwaseong-si (KR); Won Sik Son, Yongin-si (KR); Tae Hee Kim, Yongin-si (KR)

(73) Assignee: SEMES CO., LTD., Cheonan-si (KR)

(21) Appl. No.: 18/145,245

(22) Filed: Dec. 22, 2022

(30) Foreign Application Priority Data
Dec. 30, 2021 (KR) 10-2021-0192294
Jun. 16, 2022 (KR) 10-2022-0073628

(51) Int. Cl. B23K 26/03; G03F 1/84; G03F 1/42; G03F 1/60; B23K 26/122; B23K 26/06; B23K 26/04; B23K 26/362

(52) U.S. Cl. CPC B23K 26/032; G03F 1/84; G03F 1/42; G03F 1/60; B23K 26/122; B23K 26/0648; B23K 26/043; B23K 26/362

(57) ABSTRACT

The inventive concept provides a mask treating method. The mask treating method includes treating a mask by supplying a liquid to the mask, and irradiating a laser to a region of the mask on which a specific pattern is formed while the liquid remains on the mask; moving an optical module including a laser unit configured to irradiate the laser between a process position for treating the substrate and a standby position deviating from the process position; and adjusting a state of the optical module at an inspection port provided at the standby position to a set condition before the optical module is moved to the process position.

### CROSS-REFERENCE TO RELATED APPLICATIONS

This application claims priority under 35 U.S.C. § 119 to Korean Patent Application No. 10-2021-0192294 filed on Dec. 30, 2021 and Korean Patent Application No. 10-2022-0073628 filed on Jun. 16, 2022, in the Korean Intellectual Property Office, the disclosures of which are incorporated by reference herein in their entireties.

### BACKGROUND

Embodiments of the inventive concept described herein relate to a substrate treating apparatus and a substrate treating method, more specifically, a substrate treating apparatus and a substrate treating method for treating a substrate by heating the substrate.

The photolithography process for forming a pattern on the wafer includes an exposing process. The exposing process is an operation which is previously performed for cutting a semiconductor integrated material attached to the wafer into a desired pattern. The exposing process may have various purposes such as forming a pattern for an etching and forming a pattern for the ion implantation. In the exposing process, the pattern is drawn in on the wafer with a light using a mask, which is a kind of ‘frame’. When the light is exposed to the semiconductor integrated material on the wafer, for example, a resist on the wafer, chemical properties of the resist change according to a pattern by the light and the mask. When a developing liquid is supplied to a resist which chemical properties have changed according to the pattern, the pattern is formed on the wafer.

In order to precisely perform the exposing process, the pattern formed on the mask must be precisely manufactured. It must be checked whether the pattern is formed to satisfy a process condition. A large number of patterns are formed on one mask. That is, it takes a lot of time for an operator to inspect all of the large number of patterns to inspect one mask. Accordingly, a monitoring pattern capable of representing one pattern group including a plurality of patterns is formed on the mask. In addition, an anchor pattern that may represent a plurality of pattern groups are formed on the mask. The operator may estimate whether patterns included in one pattern group are good or not through inspecting the monitoring pattern. In addition, the operator may estimate whether the patterns formed on the mask are good or not through inspecting the anchor pattern.

Also, in order to increase an accuracy of the mask inspection, it is preferable that critical dimension of the monitoring pattern and the anchor pattern are the same. A critical dimension correction process is performed additionally to precisely correct a critical dimension of patterns formed at the mask.

FIG. 1 illustrates a normal distribution regarding a first critical dimension CDP1 of the monitoring pattern of the mask and a second critical dimension CDP2 (a critical dimension of the anchor pattern) before a critical dimension correction process is performed during a mask manufacturing process. In addition, the first critical dimension CDP1 and the second critical dimension CDP2 have a size smaller than a target critical dimension. Before the critical dimension correction process is performed, there is a deliberate deviation between the critical dimension of the monitoring pattern and the anchor pattern (CD, critical dimension). And, by additionally etching the anchor pattern in the critical dimension correction process, the critical dimension of these two patterns are made the same. In the process of over-etching the anchor pattern, if the anchor pattern is more over-etched than the monitoring pattern, a difference in the critical dimension of the monitoring pattern and the anchor pattern occurs, and thus the critical dimension of the patterns formed at the mask may not be accurately corrected. When additionally etching the anchor pattern, a precise etching of the anchor pattern should be accompanied.

In an etching process of etching the anchor pattern, a treating liquid is supplied to the mask, and the anchor pattern formed on the mask supplied with the treating liquid is heated using a laser. In order to be accompanied by the precise etching of the anchor pattern, a laser must be precisely irradiated to a specific region at which the anchor pattern is formed. In order for the laser to be precisely irradiated to the anchor pattern, the laser irradiated to the anchor pattern must be set to have a set condition. The set condition may be a condition in which the anchor pattern formed on the mask may be uniformly heated. In addition, the set condition may be a condition in which the anchor pattern formed on the mask may be collectively heated.

If the laser is irradiated to the anchor pattern formed on the mask without being set to the set conditions, a heating may not be performed on a partial region of the anchor pattern. In addition, the laser is unevenly irradiated to the anchor pattern, which hinders the precise etching of the anchor pattern.

### SUMMARY

Embodiments of the inventive concept provide a substrate treating apparatus and a substrate treating method for performing a precise etching with respect to a substrate.

Embodiments of the inventive concept provide a substrate treating apparatus and a substrate treating method for precisely heating a specific region of the substrate.

Embodiments of the inventive concept provide a substrate treating apparatus and a substrate treating method for adjusting a state of an optical module to a condition at which a specific region of a substrate may be precisely heated at an inspection port providing a standby position before the specific region of the substrate is heated.

The technical objectives of the inventive concept are not limited to the above-mentioned ones, and the other unmentioned technical objects will become apparent to those skilled in the art from the following description.

The inventive concept provides a substrate treating method. The substrate treating method includes treating a substrate by supplying a liquid to the substrate, and irradiating a laser to a region of the substrate on which a specific pattern is formed while the liquid remains on the substrate; moving an optical module including a laser unit configured to irradiate the laser between a process position for treating the substrate and a standby position deviating from the process position; and adjusting a state of the optical module at an inspection port provided at the standby position to a set condition before the optical module is moved to the process position.

In an embodiment, the standby position includes an outer region of a treating container surrounding a support unit supporting the substrate.

In an embodiment, the adjusting the state of the optical module includes an adjusting an irradiation position for adjusting the irradiation position of the laser.

In an embodiment, the inspection port includes a first detection member for displaying a reference point and for checking the irradiation position of the laser, and wherein the adjusting the irradiation position is performed if the laser unit irradiates the laser toward the first detection member and if the irradiation position of the laser irradiated to the first detection member deviates from the reference point.

In an embodiment, the adjusting the irradiation position adjusts the irradiation position of the laser irradiated to the first detection member to the reference point by moving the optical module.

In an embodiment, the optical module further includes an imaging unit configured to image a region to which the laser is irradiated, and the adjusting the state of the optical module further includes an adjusting an imaging region for aligning the imaging region of the imaging unit with the irradiation position of the laser.

In an embodiment, the inspection port includes a first detection member for displaying the reference point and checking the irradiation position of the laser, and the laser unit irradiates the laser to the first detection member, the imaging unit images the first detection member and acquires an image including the laser irradiated to the first detection member, and the adjusting the imaging region is performed if the imaging region deviates from the irradiation position of the laser irradiated to the first detection member.

In an embodiment, the adjusting the imaging region adjusts a tilting angle of a lens acquired at an imaging path, to adjust a center of the imaging region to a center of the laser irradiated to the reference point.

In an embodiment, the adjusting the state of the optical module includes an adjusting a profile for adjusting any one of a diameter of the laser, a steepness of the laser, and a uniformity of the laser, based on a detected profile of the laser, which is detected by detecting the profile of the laser irradiated from the laser unit.

In an embodiment, the inspection port includes a second detection member for detecting the profile of the laser, and the laser unit irradiates the laser to the second detection member, and second detection member detects the profile of the laser which is irradiated, and the adjusting the profile is performed if the profile detected by the second detection member deviates from a reference range of the profile having the set condition.

In an embodiment, the reference range includes a diameter range of the laser, and the optical module moves in a vertical direction to adjust the diameter of the laser, if the profile of the laser detected at the second detection member deviates from the diameter range at the adjusting the profile.

In an embodiment, the reference range includes a steepness range of the laser, and the optical module moves in the vertical direction to adjust a steepness of the laser, if the second detection member deviates from the steepness range of the profile of the laser which is detected by the second detection member at the adjusting the profile.

In an embodiment, the reference range includes a uniformity range of the laser, and an interlock is generated or a position and/or an angle of an optical system which is positioned on a path of the laser irradiated by the laser unit is adjusted, if the second detection member deviates from the uniformity range of the profile of the laser which is detected by the second detection member at the adjusting the profile.

In an embodiment, the inspection port includes: a first detection member displaying a reference point and which checks an irradiation position of the laser; and a second detection member for detecting a profile of the laser, and wherein the adjusting the state of the optical module comprises: adjusting the irradiation position for adjusting the irradiation position of the laser; adjusting an imaging region for moving the imaging region for imaging the laser to a position at which the laser is irradiated; and adjusting the profile for adjusting the profile of the laser irradiated from the laser unit to a reference range of the profile having a set condition, based on a detection of the laser unit of the profile of the laser irradiated toward the second detection member, and the profile of the detected laser.

In an embodiment, the substrate includes a mask, and the mask has a first pattern and a second pattern which is different from the first pattern, the first pattern is formed within a plurality of cells formed at the mask, the second pattern is formed outside the plurality of cells, and the specific pattern is the second pattern.

In an embodiment, the liquid is supplied to a substrate in which a rotation has stopped, and the laser is irradiated to the substrate in which the rotation is stopped.

The inventive concept provides a substrate treating method. The substrate treating method includes supplying a treating liquid to a substrate to form a puddle; irradiating a laser to the substrate to which the treating liquid is supplied; supplying a rinsing liquid to the substrate; and adjusting a state of an optical module for irradiating the laser to a set condition, at an inspection port positioned at an outside region of a treating container surrounding a support unit for supporting the substrate, and wherein the optical module for irradiating the laser at the supplying the treating liquid, the supplying the rinsing liquid, and the adjusting the state of the optical module is positioned at a standby position, and the optical module is positioned at a process position at the irradiating the laser to the substrate, and wherein the process position is a position at which the substrate corresponds to a top side of the support unit supporting the substrate, the standby position is a position corresponding to a top side of the inspection port.

In an embodiment, the liquid treating step supplies the treating liquid to a substrate in which a rotation is stopped, the irradiating the laser irradiates the laser to the substrate in which the rotation is stopped, and the supplying a rinsing liquid supplies the rinsing liquid to the substrate in which the rotation is stopped.

In an embodiment, the optical module comprises: a laser unit for irradiating the laser; and an imaging unit for imaging a region to which the laser is irradiated, and wherein the inspection port comprises: a first detection member displaying a reference point and checking an irradiation position of the laser and an imaging region of the imaging unit; and a second detection member for detecting a profile of the laser, and wherein the adjusting a state of the optical module comprises: adjusting an irradiation position for adjusting a center point of the laser which is irradiated to the first detection member to the reference point; adjusting an imaging region for aligning the imaging region to the center point of the laser which has been adjusted to the reference point; and adjusting a profile for detecting the profile of the laser which is irradiated toward to the second irradiation member by the laser unit, adjusting the profile of the measured laser to a reference range of the profile having the set condition.

In an embodiment, the supplying the treating liquid, the irradiating the laser to the substrate, the supplying the rinsing liquid is performed sequentially, and the adjusting the state of the optical module is performed before the supplying the treating liquid or between the supplying the treating liquid and the irradiating the laser to the substrate.

The inventive concept provides a substrate treating apparatus. The substrate treating apparatus includes a support unit configured to support a substrate; a liquid supply unit configured to supply a liquid to the substrate supported by the support unit; an inspection port provided at a standby position; and an optical module moving between the standby position and a process position for treating the substrate supported on the support unit, and wherein the optical module comprises: a laser unit for irradiating a laser to the substrate having a set condition supported on the support unit; and an imaging unit configured to acquire an image by imaging the laser irradiated from the laser unit, and wherein the inspection port comprises: a first detection member for checking an irradiation position of the laser and an imaging region of the imaging unit; and a second detection member for inspecting a profile of the laser.

In an embodiment, the substrate treating apparatus further comprising a controller, and wherein the controller moves the optical module so a center position of the laser irradiated to the first detection member by the laser unit is adjusted to a reference point displayed at the first detection member from a standby position, before the optical module is moved to a process position.

In an embodiment, the controller controls a tilting angle of a lens acquired at an imaging path, to adjust an imaging region of the imaging unit to be aligned to a center of the laser having a position adjusted to the reference point.

In an embodiment, the controller moves the optical module to a top side of the second detection member from a top side of the first detection member, and the laser unit irradiates the laser to the second detection member while the optical module is positioned at the top side of the second detection member, and adjusts a diameter of the laser by moving the optical module in the vertical direction by a first distance.

In an embodiment, the controller adjusts a steepness of the laser by moving the optical module by a second distance which is smaller than the first distance in the vertical direction, if the profile detected by the second detection member deviates from a steepness of the laser having the set condition.

In an embodiment, the controller adjusts a uniformity range of the laser, by generating an interlock adjusting a position and/or an angle of an optical system which is positioned on a path of the laser irradiated by the laser unit, if the profile detected by the second detection member deviates from a uniformity range of the laser having the set condition, and the optical module moves from the top side of the first detection member to the top side of the second detection member, and irradiates the laser to the second detection member by the laser unit, while the optical module is positioned at the top of the second detection member.

According to an embodiment of the inventive concept, a precise etching with respect to a substrate may be performed.

According to an embodiment of the inventive concept, a specific region of a substrate may be precisely heated.

According to an embodiment of the inventive concept, a state of an optical module may be adjusted to a condition at which a specific region of a substrate may be precisely heated at an inspection port providing a standby position before the specific region of the substrate is heated.

According to an embodiment of the inventive concept, a specific region of a substrate may be comprehensively heated by adjusting a state of an optical module.

According to an embodiment of the inventive concept, a specific region of substrate may be uniformly heated by adjusting a state of an optical module.

The effects of the inventive concept are not limited to the above-mentioned ones, and the other unmentioned effects will become apparent to those skilled in the art from the following description.

### BRIEF DESCRIPTION OF THE FIGURES

The above and other objects and features will become apparent from the following description with reference to the following figures, wherein like reference numerals refer to like parts throughout the various figures unless otherwise specified, and wherein:

FIG. 1 illustrates a normal distribution of a critical dimension of a monitoring pattern and a critical dimension of an anchor pattern.

FIG. 2 is a plan view schematically illustrating a substrate treating apparatus according to an embodiment of the inventive concept.

FIG. 3 schematically illustrates a substrate treated in a chamber of FIG. 2 seen from above.

FIG. 4 is an enlarged view schematically illustrating an embodiment of a second pattern formed on the substrate of FIG. 3 seen from above.

FIG. 5 schematically illustrates an embodiment of the chamber of FIG. 2.

FIG. 6 is a view of a chamber according to an embodiment of FIG. 5 seen from above.

FIG. 7 is a perspective view of an optical module according to an embodiment of FIG. 5.

FIG. 8 schematically illustrates the optical module according to an embodiment of FIG. 5 viewed from a side.

FIG. 9 schematically illustrates the optical module according to an embodiment of FIG. 5 seen from above.

FIG. 10 schematically illustrates an inspection port according to an embodiment of FIG. 5 seen from above.

FIG. 11 schematically illustrates a state in which a first detection member and a second detection member are viewed from a side according to an embodiment of FIG. 5.

FIG. 12 is a flowchart of a substrate treating method according to an embodiment of the inventive concept.

FIG. 13 schematically illustrates a state in which an error between an irradiation position of a laser irradiated to the first detection member and a reference point is confirmed.

FIG. 14 schematically illustrates the optical module performing an irradiation position adjustment step according to an embodiment of FIG. 12 after the error between the irradiation position of the laser and the reference point is confirmed.

FIG. 15 schematically illustrates a state in which the irradiation position of the laser irradiated to the first detection member is adjusted to the reference point after the irradiation position adjustment step of FIG. 14 is performed.

FIG. 16 schematically illustrates an error confirmed between the irradiation position of the laser irradiated to the first detection member and an imaging region of an imaging unit.

FIG. 17 schematically illustrates the optical module performing an imaging region adjustment step according to an embodiment of FIG. 12 after the error between the irradiation position of the laser and the imaging region is confirmed.

FIG. 18 schematically illustrates a state in which the imaging region is adjusted to the irradiation position of the laser irradiated to the first detection member after the imaging region adjustment step of FIG. 17 is performed.

FIG. 19 illustrates a state of the optical module moving from the first detection member to the second detection member which is seen from above after both the irradiation position adjustment step and the imaging region adjustment step of FIG. 12 are performed.

FIG. 20 is a graph illustrating a diameter range of a profile reference range of a laser having a set condition.

FIG. 21 is a front view of the optical module irradiating the laser to the second detection member.

FIG. 22 is a graph schematically illustrating a state in which a profile of a laser measured at the second measuring member of FIG. 21 does not satisfy a diameter range.

FIG. 23 is an enlarged view schematically showing that the optical module irradiates the laser to the second detection member after performing a profile adjustment step of FIG. 12 by moving the optical module.

FIG. 24 is a graph schematically illustrating a state in which the profile of the laser measured at the second detection member of FIG. 23 satisfies the diameter range.

FIG. 25 is a graph illustrating a steepness range among the profile reference range of the laser having the set condition.

FIG. 26 is a graph schematically illustrating a state in which the profile of the laser measured in the second detection member of FIG. 23 does not satisfy the steepness range.

FIG. 27 is an enlarged view illustrating the optical module irradiating the laser to the second detection member after the profile adjustment step of FIG. 12 is performing by moving the optical module.

FIG. 28 is a graph schematically illustrating a state in which the profile of the laser measured at the second detection member of FIG. 27 satisfies the steepness range.

FIG. 29 is a graph illustrating a uniformity range among the profile reference range of the laser having the set condition.

FIG. 30 is a graph illustrating an embodiment of calculating the uniformity range of FIG. 29.

FIG. 31 schematically illustrates a state of the substrate treating apparatus performing a liquid treating step of FIG. 12.

FIG. 32 schematically illustrates a state of the substrate treating apparatus performing an irradiation step of FIG. 12.

FIG. 33 schematically illustrates a state of the substrate treating apparatus performing a rinsing step of FIG. 12.

FIG. 34 and FIG. 35 are flowcharts of the substrate treating method according to another embodiment of the inventive concept of FIG. 12.

FIG. 36 schematically illustrates a front view of another embodiment of the second detection member according to an embodiment of FIG. 5.

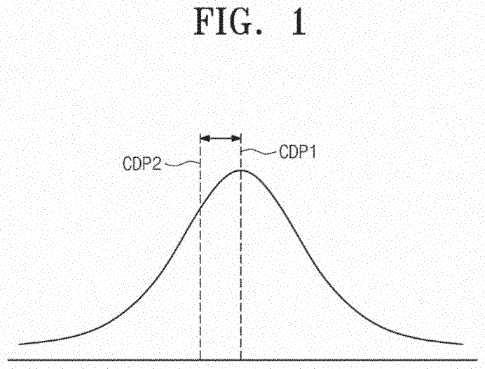

### DETAILED DESCRIPTION

The inventive concept may be variously modified and may have various forms, and specific embodiments thereof will be illustrated in the drawings and described in detail. However, the embodiments according to the concept of the inventive concept are not intended to limit the specific disclosed forms, and it should be understood that the present inventive concept includes all transforms, equivalents, and replacements included in the spirit and technical scope of the inventive concept. In a description of the inventive concept, a detailed description of related known technologies may be omitted when it may make the essence of the inventive concept unclear.

The terminology used herein is for the purpose of describing particular embodiments only and is not intended to be limiting of the inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Also, the term “exemplary” is intended to refer to an example or illustration.

It will be understood that, although the terms “first”, “second”, “third”, etc., may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the inventive concept.

Hereinafter, embodiments of the inventive concept will be described in detail with reference to the accompanying drawings.

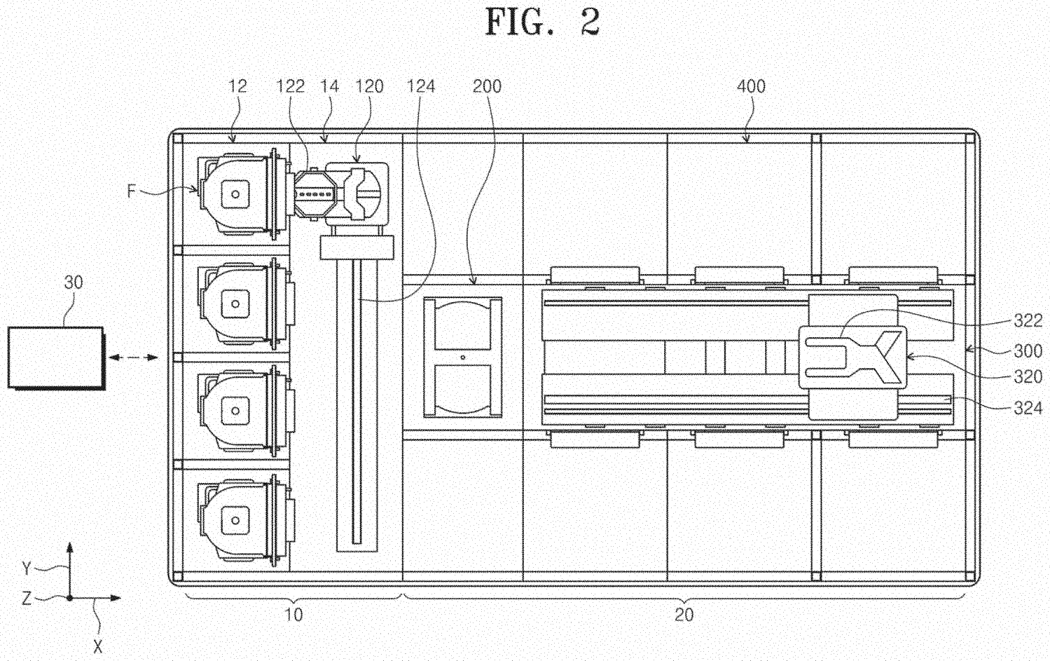

Hereinafter, an embodiment of the inventive concept will be described in detail with reference to FIG. 2 to FIG. 36. FIG. 2 is a plan view schematically illustrating a substrate treating apparatus according to an embodiment of the inventive concept.

Referring to FIG. 2, the substrate treating apparatus includes an index module 10, a treating module 20, and a controller 30. According to an embodiment, when seen from above, the index module 10 and the treating module 20 may be disposed along a direction.

Hereinafter, a direction in which the index module 10 and the treating module 20 are disposed is defined as a first direction X, a direction perpendicular to the first direction X when seen from above is defined as a second direction Y, and a direction perpendicular to a plane including both the first direction X and the second direction Y is defined as a third direction Z.

The index module 10 transfers a substrate M. The index module 10 transfers the substrate M between a container F in which the substrate M is stored and the treating module 20. For example, the index module 10 transfers the substrate M on which a predetermined treatment has been completed at the treating module 20 to the container F. For example, the index module 10 transfers the substrate on which a predetermined treatment has been completed at the treating module 20 from the container F to the treating module 20. A lengthwise direction of the index module 10 may be formed in the second direction Y.

The index module 10 may have a load port 12 and an index frame 14. The container F in which the substrate M is stored is seated on the load port 12. The load port 12 may be positioned on an opposite side of the treating module 20 with respect to the index frame 14. A plurality of load ports 12 may be provided in the index module 10. The plurality of load ports 12 may be arranged in a line along the second direction Y. The number of load ports 12 may increase or decrease according to a process efficiency and foot print conditions, etc of the treating module 20.

As the container F, a sealing container such as a front opening unified pod (FOUP) may be used. The container F may be placed on the load port 12 by a transfer means (not shown) such as an overhead transfer, an overhead conveyor, or an automatic guided vehicle, or by an operator.

The index frame 14 may have a transfer space for transferring the substrate M. An index robot 120 and an index rail 124 may be provided at the transfer space of the index frame 14. The index robot 120 transfers the substrate M. The index robot 120 may transfer the substrate M between the index module 10 and the buffer unit 200 to be described later. The index robot 120 includes an index hand 122.

The substrate M may be placed on the index hand 122. The index hand 122 may be provided to be forwardly and backwardly movable, rotatable in the vertical direction (for example, the third direction Z), and movable along an axial direction. A plurality of index hands 122 may be provided to be placed on the index frame 14. The plurality of index hands 122 may each be spaced apart from each other in an up/down direction. The plurality of hands 122 may be forwardly and backwardly movable independently of each other.

The index rail 124 is placed in the transfer space of the index frame 14. The index rail 124 may be provided with its lengthwise direction along the second direction Y. The index robot 120 may be placed on the index rail 124, and the index robot 120 may be movable along the index rail 124. That is, the index robot 120 may forwardly and backwardly move along the index rail 124.

The controller 30 may comprise a process controller consisting of a microprocessor (computer) that executes a control of the substrate treating apparatus, a user interface such as a keyboard via which an operator inputs commands to manage the substrate treating apparatus, and a display showing the operation situation of the substrate treating apparatus, and a memory unit storing a treating recipe, i.e., a control program to execute treating processes of the substrate treating apparatus by controlling the process controller or a program to execute components of the substrate treating apparatus according to data and treating conditions. In addition, the user interface and the memory unit may be connected to the process controller. The treating recipe may be stored in a storage medium of the storage unit, and the storage medium may be a hard disk, a portable disk, such as a CD-ROM or a DVD, or a semiconductor memory, such as a flash memory.

The controller 30 can control components of the substrate treating apparatus so the substrate treating method described below can be performed. For example, the controller 30 may control components of the chamber 400 mentioned below.

The treating module 20 may include a buffer unit 200, a transfer frame 300, and a chamber 400.

The buffer unit 200 has a buffer space. The buffer space functions as a space in which the substrate M taken into the treating module 20 and the substrate M taken out from the treating module 20 temporarily remain. The buffer unit 200 may be disposed between the index frame 14 and the transfer frame 300. The buffer unit 200 may be positioned at an end of the transfer frame 300. The slots (not shown) on which the substrate M is placed may be installed in the buffer space inside the buffer unit 200. A plurality of slots (not shown) may be vertically spaced apart from each other.

In the buffer unit 200, a front face and a rear face are opened. The front face may be a surface facing the index frame 14. The rear face may be a surface facing the transfer frame 300. The index robot 120 may access the buffer unit 200 through the front face of the buffer unit 200. The transfer robot 320 to be described later may access the buffer unit 200 through the rear face of the buffer unit 200.

The transfer frame 300 provides a space for transferring the substrate M between the buffer unit 200 and the chamber 400. The transfer frame 300 may have a lengthwise direction in a direction horizontal to the first direction X. The chambers 400 may be disposed on the side of the transfer frame 300. The transfer frame 300 and the chamber 400 may be disposed in the second direction Y. According to an embodiment, the chambers 400 may be disposed on both side surfaces of the transfer frame 300. The chambers 400 disposed on a side of the transfer frame 300 may have an array of A×B (A, B are natural numbers greater than 1 or 1), respectively, along the first direction X and the third direction Z.

The transfer frame 300 has a transfer robot 320 and a transfer rail 324. The transfer robot 320 transfers the substrate M. The transfer robot 320 transfers the substrate M between the buffer unit 200 and the chamber 400. The transfer robot 320 includes a hand 322. The substrate M may be placed on the hand 322. The hand 322 may be forwardly and backwardly movable, rotatable in a vertical direction (e.g., the third direction Z) as an axis, and movable in an axial direction. The transfer robot 320 may include a plurality of hands 322. The plurality of hands 322 may be disposed to be spaced apart in the vertical direction. In addition, the plurality of hands 322 may be forwardly and backwardly movable independently of each other.

The transfer rail 324 may be formed in the transfer frame 300 in a direction horizontal to a lengthwise direction of the transfer frame 300. For example, the lengthwise direction of the transfer rail 324 may be a direction horizontal to the first direction X. The transfer robot 320 is placed on the transfer rail 324, and the transfer robot 320 may move along the transfer rail 324.

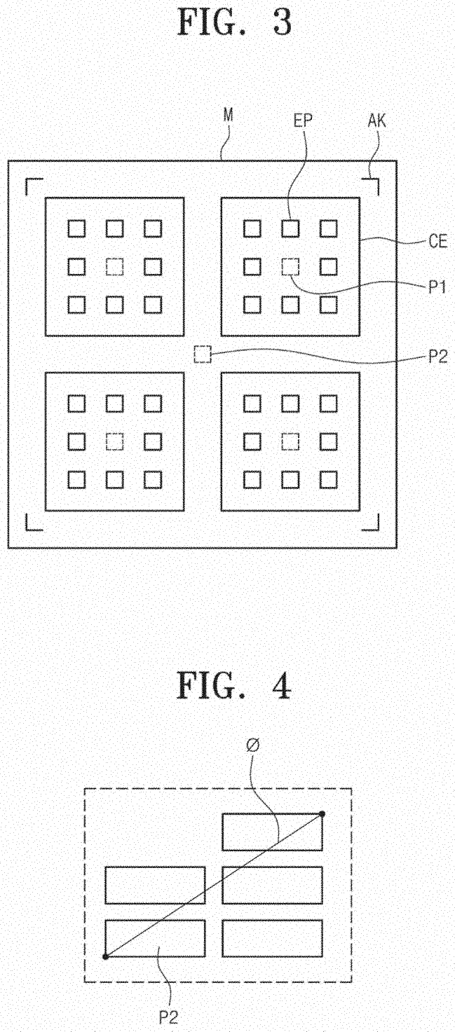

FIG. 3 schematically illustrates the substrate treated in the chamber of FIG. 2 seen from above. FIG. 4 is an enlarged view schematically illustrating an embodiment of a second pattern formed on the substrate of FIG. 3 as seen from above. Hereinafter, the substrate M treated in the chamber 400 according to an embodiment of the inventive concept will be described in detail.

An The object to be treated in the chamber 400 illustrated in FIG. 2 may be any one of a wafer, a glass, and a photo mask. The substrate M treated in the chamber 400 according to an embodiment may be a photomask which is a “frame” used during an exposing process. For example, the substrate M may have a rectangular shape. A reference mark AK, a first pattern P1, and a second pattern P2 may be formed on the substrate M.

At least one reference mark AK may be formed on the substrate M. For example, the reference mark AK is a number corresponding to the number of corners of the substrate M and may be formed in a corner region of the substrate M.

The reference mark AK may be used to align the substrate M. In addition, the reference mark AK may be a mark used to derive a position information of the substrate M supported by the support unit 420 to be described later. For example, the imaging unit 700 to be described later may acquire an image including the reference mark AK by imaging the reference mark AK, and transmit the acquired image to the controller 30. The controller 30 may detect an accurate position of the substrate M by analyzing the image including the reference mark AK. In addition, the reference mark AK may be used to derive the position information of the substrate M when the substrate M is transferred. Accordingly, the reference mark AK may be defined as a so-called align key.

At least one cell CE may be formed on the substrate M. A plurality of patterns may be formed in each of the plurality of cells CE. The patterns formed in each cell CE may be defined as one pattern group. The pattern formed in each cell CE may include an exposure pattern EP and a first pattern P1.

The exposure pattern EP may be used to form an actual pattern on the substrate M. A plurality of exposure patterns EP may be formed in the cell CE. The first pattern P1 may be a pattern representing the exposure patterns EP formed in one cell CE. If a plurality of cells CE are provided, a plurality of first patterns P1 may be provided. For example, a first pattern P1 may be formed in each of a plurality of cells CE. However, the inventive concept is not limited thereto, and the plurality of first patterns P1 may be formed in one cell CE.

The first pattern P1 may have a shape in which some of the exposure patterns EP are combined. The first pattern P1 may be defined as a so-called monitoring pattern. An average value of a critical dimension of the plurality of first patterns P1 may be defined as a critical dimension monitoring macro (CDMM).

If the operator inspects the first pattern P1 formed in any one cell CE through a scanning electron microscope (SEM), it is possible to estimate whether the shapes of the exposure patterns EP formed in any one cell CE are good or not. Accordingly, the first pattern P1 may function as an inspection pattern. Unlike the above-described example, the first pattern P1 may be any one of the exposure patterns EPs participating in an actual exposing process. Selectively, the first pattern P1 may be the inspection pattern and may be a pattern participating in an actual exposing process at the same time.

The second pattern P2 may be formed outside the cells CE formed on the substrate M. For example, the second pattern P2 may be formed in an outer region of a region at which a plurality of cells CE are formed. The second pattern P2 may be a pattern representing the exposure patterns EP formed on the substrate M. The second pattern P2 may be defined as an anchor pattern. At least one or more second patterns P2 may be formed on the substrate M. As shown in FIG. 4, a plurality of second patterns P2 may be formed on the substrate M. The plurality of second patterns P2 may be arranged in a combination of series and/or parallel. For example, five second patterns P2 may be formed on the substrate M, and five second patterns P2 may be arranged in a combination of two rows and three rows. Selectively, the plurality of second patterns P2 may have a shape in which some of the first patterns P1 are combined.

A distance having the largest value among a distance from a corner end of any one second pattern P2 to a corner end of another one second pattern P2 may be defined as a maximum length (Φ) of the second pattern P2. For example, as shown in FIG. 4, a distance from a left corner of the second pattern P2 positioned in a first column and a first row to the top right corner of the second pattern P2 positioned in the second column and the third row may be the maximum length (Φ) of the second pattern P2. A point corresponding to half of the distance from the bottom left corner of the second pattern P2 positioned in the first column and the first row to the top right corner of the second pattern P2 positioned in the second column and the third row may be defined as a center CP of a specific region at which the second pattern P2 is formed.

If the operator inspects the second pattern P2 through a scanning electron microscope (SEM), it is possible to estimate whether the shapes of the exposure patterns EPs formed on one substrate M are good or not. Accordingly, the second pattern P2 may function as an inspection pattern. The second pattern P2 may be an inspection pattern which does not participate in an actual exposing process. In addition, the second pattern P2 may be a pattern for setting a process condition of the exposure apparatus.

A treating process performed in the chamber 400 to be described later may be a Fine Critical Dimension Correction (FCC) in a mask manufacturing process for the exposing process. In addition, the substrate M treated in the chamber 400 may be the substrate M on which a pre-treatment has been performed. The critical dimensions of the first pattern P1 and the second pattern P2 formed on the substrate M taken into the chamber 400 may be different from each other. According to an embodiment, a critical dimension of the first pattern P1 may be relatively greater than a critical dimension of the second pattern P2. For example, the critical dimension of the first pattern P1 may have a first width (e.g., 69 nm), and the critical dimension of the second pattern P2 may have a second width (e.g., 68.5 nm).

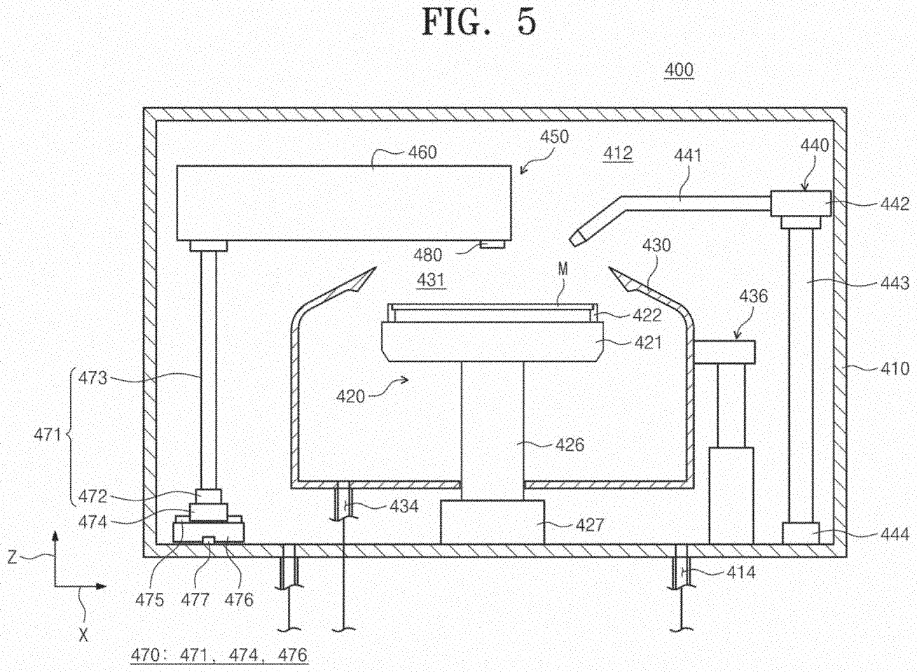

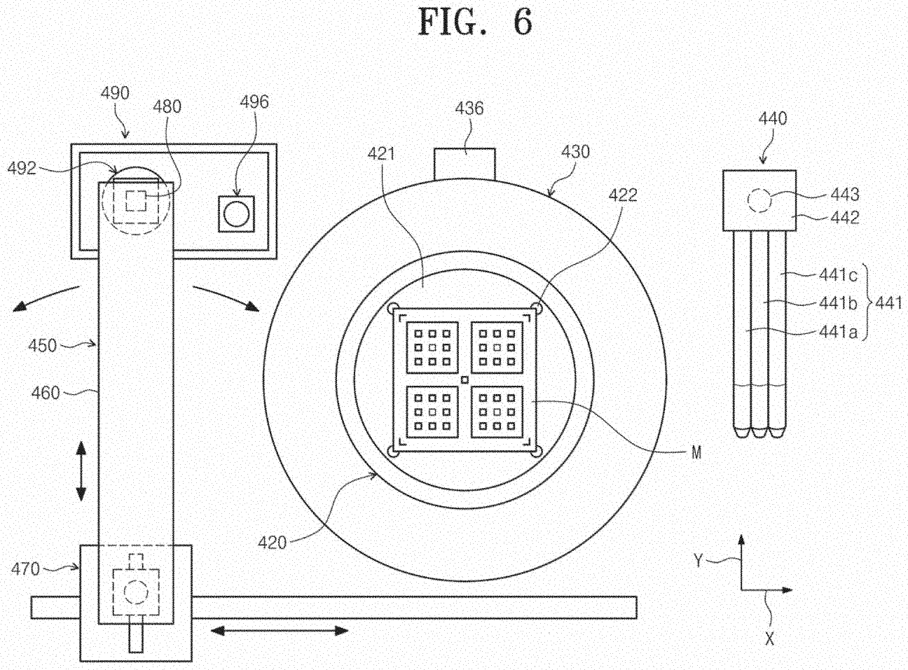

FIG. 5 schematically illustrates an embodiment of the chamber of FIG. 2. FIG. 6 is a view of a chamber according to an embodiment of FIG. 5 as seen from above. Referring to FIG. 5 and FIG. 6, the chamber 400 may include a housing 410, a support unit 420, a treating container 430, a liquid supply unit 440, an optical module 450, and an inspection port 490.

The housing 410 may have a substantially rectangular shape. The housing 410 has an inner space 412. The support unit 420, the treating container 430, the liquid supply unit 440, the optical module 450, and the inspection port 490 may be positioned in the inner space 412.

An opening (not shown) through which the substrate M is taken out may be formed at the housing 410. The opening (not shown) may be selectively opened and closed by a door assembly which is not shown. An inner wall surface of the housing 410 may be coated with a material having a high corrosion resistance. As the inner wall surface of the housing 410 is coated, it is possible to prevent the inner wall of the housing 410 from being corroded by a liquid supplied by the liquid supply unit 440 to be described later.

An exhaust hole 414 is formed on a bottom surface of the housing 410. The exhaust hole 414 is connected to a depressurizing member (not shown). For example, the depressurizing member (not shown) may be a pump. The exhaust hole 414 exhausts an atmosphere of the inner space 412. In addition, the exhaust hole 414 discharges byproducts such as particles generated in the inner space 412 to the outside of the inner space 412.

The support unit 420 is positioned in the inner space 412. The support unit 420 supports the substrate M. In addition, the support unit 420 rotates the substrate M. The support unit 420 may include a body 421, a support pin 422, a support shaft 426, and a driver 427.

The body 421 may generally have a plate shape. The body 421 may have a plate shape having a predetermined thickness. A top surface of the body 421 may have a substantially circular shape when seen from above. The top surface of the body 421 may have a relatively larger area than the top and bottom surfaces of the substrate M.

The support pin 422 supports the substrate M. The support pin 422 may support the substrate M to separate the bottom surface of the substrate M from the top surface of the body 421. The support unit 420 may include a plurality of support pins 422. For example, there may be four supporting pins 422. The plurality of support pins 422 may be disposed at positions corresponding to each of the corner regions of the substrate M having a rectangular shape.

The support pin 422 may have a substantially circular shape when seen from above. The support pin 422 may have a shape in which a portion corresponding to a corner region of the substrate M is downwardly recessed. The support pin 422 may have a first surface and a second surface. For example, the first surface may support a bottom end of the corner region of the substrate M. In addition, the second surface may face a side end of the corner region of the substrate M. Accordingly, the second surface may limit a lateral separation of the substrate M if the substrate M rotates.

The support shaft 426 is coupled to the body 421. The support shaft 426 is coupled to a bottom part of the body 421. The support shaft 426 may move in the vertical direction (e.g., in the third direction Z) by the driver 427. In addition, the support shaft 426 may be rotated by the driver 427. The driver 427 may be a motor. If the driver 427 rotates the support shaft 426, the body 421 coupled to the support shaft 426 may rotate. Accordingly, the substrate M may rotate together with a rotation of the body 421 through the support pin 422.

According to an embodiment, the support shaft 426 may be a hollow shaft. Also, the driver 427 may be a hollow motor. A fluid supply line which is not shown may be disposed inside the hollow shaft. The fluid supply line (not shown) may supply a fluid toward the bottom surface of the substrate M. The fluid supplied to the bottom surface of the substrate M may be a treating liquid, a rinsing liquid, or an inert gas. However, unlike the above-described example, a fluid supply line (not shown) may not be disposed inside the support shaft 426.

The treating container 430 may have a shape surrounding the support unit 420. The treating container 430 may have a cylindrical shape with an open top and may have a shape surrounding the outside of the support unit 420. The inner space of the treating container 430 with the open top functions as a treating space 431. For example, the treating space 431 may be a space in which the substrate M is liquid-treated and/or heat-treated. The treating container 430 can prevent a liquid supplied to the substrate M from scattering to the housing 410, the liquid supply unit 440, and the optical module 450. In addition, the treating container 430 may prevent byproducts which may occur when supplying the liquid to the substrate M or when heating the substrate M from being scattered to the housing 410, the liquid supply unit 440, and the optical module 450.

An opening into which the support shaft 426 is inserted may be formed on the bottom surface of the treating container 430 when seen from above. A discharge hole 434 through which the liquid supplied by the liquid supply unit 440 may be discharged to the outside may be formed on the bottom surface of the treating container 430. A side surface of the treating container 430 may upwardly extend from the bottom surface of the treating container 430. The top part of the treating container 430 may be inclined. For example, the top part of the treating container 430 may upwardly extend with respect to the ground toward the substrate M supported by the support unit 420.

The treating container 430 may be coupled to a lifting/lowering member 436. The lifting/lowering member 436 may move the treating container 430 in the vertical direction (e.g., in the third direction Z). The lifting/lowering member 436 may move the treating container 430 upward while the substrate M is liquid-treated or heated. In this case, a top end of the treating container 430 may be positioned relatively higher than the top end of the substrate M supported by the support unit 420. In a case in which the substrate is taken into the inner space 412, and a case in which the substrate M is taken out of the inner space 412, the lifting/lowering member 436 may downwardly move the treating container 430. In this case, the top end of the treating container 430 may be positioned relatively lower than the top end of the support unit 420.

The liquid supply unit 440 supplies the liquid to the substrate M. The liquid supply unit 440 may supply a treating liquid to the substrate M. According to an embodiment, the treating liquid may be an etching liquid. The etching liquid may etch a pattern formed on the substrate M. The etching liquid may be referred to as an etchant. The etchant may be a mixture of an ammonia, a water, and a liquid including a mixed liquid added with additives and a hydrogen peroxide. In addition, the liquid supply unit 440 may supply a rinsing liquid to the substrate M. The rinsing liquid may clean the substrate M. The rinsing liquid may be provided as a known chemical liquid.

The liquid supply unit 440 may include a nozzle 441, a fixing body 442, a rotation shaft 443, and a rotation driver 444.

The nozzle 441 supplies the liquid to the substrate M supported by the support unit 420. An end of the nozzle 441 may be coupled to the fixing body 442, and the other end of the nozzle 441 may extend in a direction away from the fixing body 442. According to an embodiment, the other end of the nozzle 441 may be bent and extended by a predetermined angle in a direction toward the substrate M supported by the support unit 420.

As illustrated in FIG. 6, the nozzle 441 may include a first nozzle 441a, a second nozzle 441b, or a third nozzle 441c. The first nozzle 441a, the second nozzle 441b, and the third nozzle 441c may supply different kinds of liquids to the substrate M.

For example, one of the first nozzle 441a, the second nozzle 441b, and the third nozzle 441c may supply the above-described treating liquid to the substrate M. In addition, the first nozzle 441a, the second nozzle 441b, and the third nozzle 441c may supply the above-described rinsing liquid to the substrate M. Another one of the first nozzle 441a, the second nozzle 441b, and the third nozzle 441c may supply a treating liquid having a different type or concentration from a treating liquid supplied by any one of the first nozzle 441a, the second nozzle 441b, and the third nozzle 441c.

The fixing body 442 fixes and supports the nozzle 441. The fixing body 442 is coupled to the rotation shaft 443. An end of the rotation shaft 443 is coupled to the fixed body 442, and the other end of the rotation shaft 443 is coupled to the rotation driver 444. The rotation shaft 443 may have a vertical lengthwise direction. For example, the rotation shaft 443 may have a lengthwise direction in a direction horizontal to the third direction Z. The rotation driver 444 rotates the rotation shaft 443. If the rotary driver 444 rotates the rotary shaft 443, the fixed body 442 coupled to the rotary shaft 443 may rotate based on the vertical axis. Accordingly, the discharge ports of the nozzles 441a, 441b, and 441c may move between a liquid supply position and a standby position.

The liquid supply position may be a position for supplying the liquid to the substrate M supported by the support unit 420. The standby position may be a position at which the liquid is not supplied to the substrate M. For example, the standby position may be a position including an outer region of the treating container 430. A home port (not shown) may be provided at a standby position at which the nozzles 441a, 441b, and 441c standby.

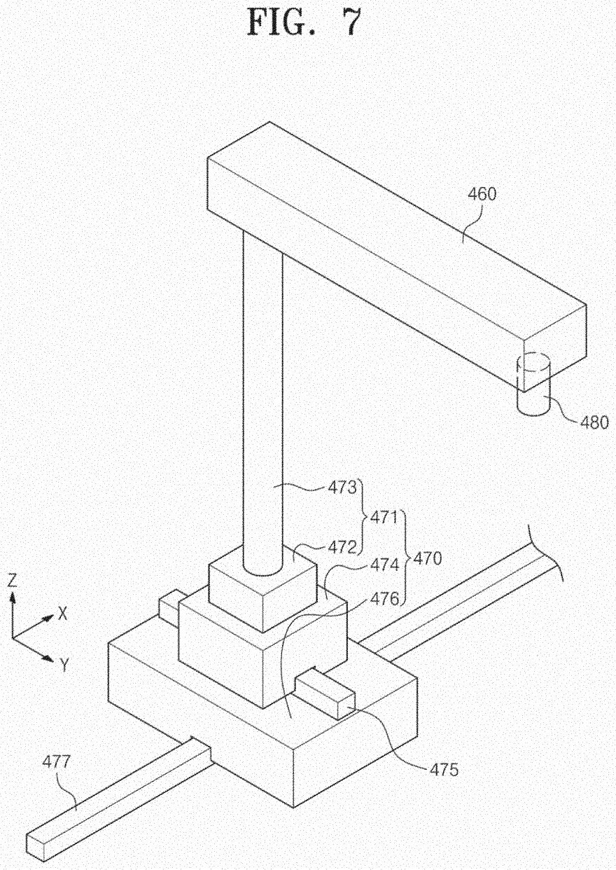

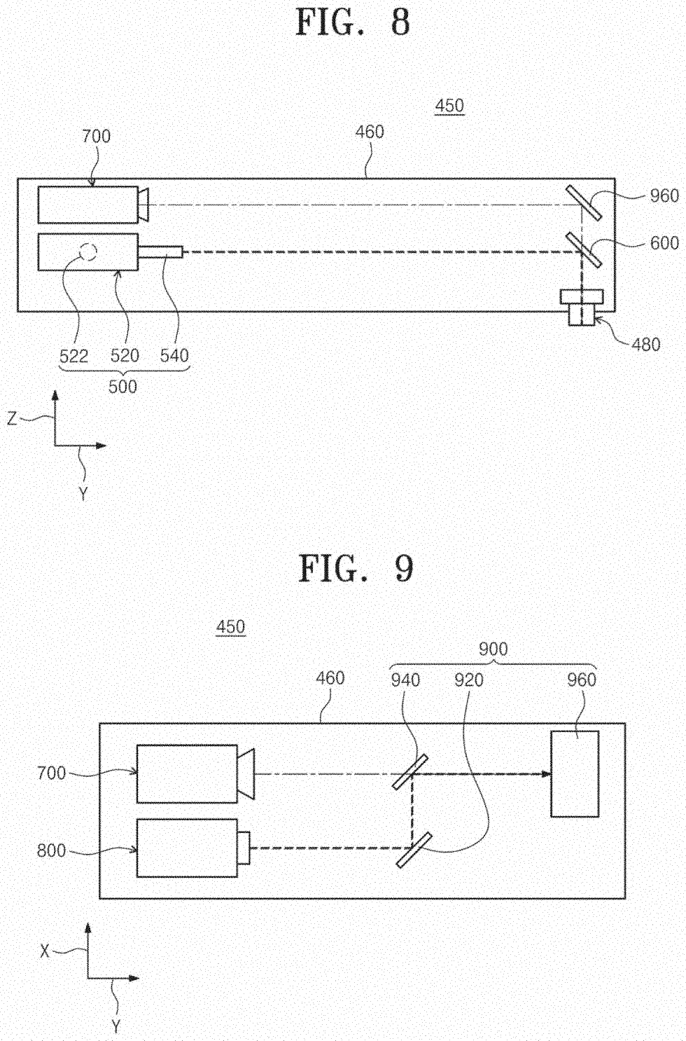

FIG. 7 is a perspective view of an optical module according to an embodiment of FIG. 5. FIG. 8 schematically illustrates the optical module according to an embodiment of FIG. 5 viewed from the side. FIG. 9 schematically illustrates the optical module according to an embodiment of FIG. 5 as seen from above. Hereinafter, the optical module according to an embodiment of the inventive concept will be described in detail with reference to FIG. 5 to FIG. 9.

The optical module 450 is positioned in the inner space 412. The optical module 450 heats the substrate M. The optical module 450 may heat the liquid-supplied substrate M. For example, the optical module 450 may heat a region in which a specific pattern is formed on the substrate M by irradiating the laser on the substrate M at which a treating liquid remains after the treating liquid is supplied to the substrate M by the liquid supply unit 440. For example, the optical module 450 may heat the second pattern P2 by irradiating the laser on a region at which the second pattern P2 illustrated in FIG. 3 and FIG. 4 is formed. A temperature of a region at which the second pattern P2 irradiated with the laser is formed may increase. Accordingly, an etching degree with respect to a region at which the second pattern P2 is formed may increase.

In addition, the optical module 450 may image a region to which the laser is irradiated. For example, the optical module 450 may obtain an image of a region including the laser irradiated from the laser unit 500 to be described later.

The optical module 450 may include a housing 460, a moving unit 470, a head nozzle 480, a laser unit 500, a bottom reflective plate 600, an imaging unit 700, a lighting unit 800, and a top reflective member 900.

The housing 460 has an installation space therein. The installation space of the housing 460 may have an environment which is sealed from the outside. In the installation space of the housing 460, a part of the head nozzle 480, a laser unit 500, an imaging unit 700, and a lighting unit 800 may be positioned. The housing 460 protects the laser unit 500, the imaging unit 700, and the lighting unit 800 from byproducts or a scattering liquid generated during a process. The head nozzle 480, the laser unit 500, the imaging unit 700, and the lighting unit 800 may be modularized by the housing 460.

An opening may be formed at a bottom of the housing 460. A part of the head nozzle 480 to be described later may be inserted into the opening formed at the housing 460. As a part of the head nozzle 480 is inserted into the opening of the housing 460, a bottom part of the head nozzle 480 may protrude from the bottom end of the housing 460.

The moving unit 470 is coupled to the housing 460. The moving unit 470 moves the housing 460. According to an embodiment, the moving unit 470 may horizontally move the housing 460 in the first direction X and the second direction Y. In addition, the moving unit 470 may vertically move the housing 460 in the third direction Z. In addition, the moving unit 470 may rotate and move the housing 460 with the third direction Z as an axis. As the moving unit 470 moves the housing 460, the head nozzle 480 inserted into the housing 460 may move.

The moving unit 470 may include a first driving unit 471, a second driving unit 474, and a third driving unit 476.

The first driving unit 471 may include a first driving unit 472 and a shaft 473. The first driving unit 472 may be a motor. The first driving unit 472 is connected to the shaft 473. The first driving unit 472 may move the shaft 473 in the vertical direction. For example, the first driving unit 472 may move the shaft 473 in the third direction Z. In addition, the first driving unit 472 may rotate the shaft 473. For example, the first driving unit 472 may rotate and move the shaft 473 with the third direction Z as an axis.

An end of the shaft 473 is connected to the first driving unit 472, and the other end of the shaft 473 is coupled to the bottom end of the housing 460. As the shaft 473 moves in the vertical direction by the first driving unit 472, the housing 460 may also move in the vertical direction. Accordingly, a height of the head nozzle 480 to be described later may be changed on a horizontal plane. In addition, as the shaft 473 rotates by the first driving unit 472, the housing 460 may also rotate. Accordingly, a position of the head nozzle 480 to be described later may be changed on a horizontal plane.

However, unlike this, there may be a plurality of first driving units 472. For example, any one of the plurality of first driving units 472 may be a rotating motor which rotates the shaft 473, and the other of the plurality of first driving units 472 may be a linear motor which moves the shaft 473 in the vertical direction.

The second driver 474 is coupled to the first driving unit 472. The second driving unit 474 may be a motor. The second driving unit 474 may move along a first rail 475 installed on a top surface of the third driving unit 476. According to an embodiment, the first rail 475 may have its lengthwise direction placed horizontal to the second direction Y. The second driving unit 474 may be forwardly and backwardly movable in the second direction Y along the first rail 475. As the second driving unit 474 is forwardly and backwardly movable in the second direction Y, the housing 460 and the head nozzle 480 may be forwardly and backwardly movable in the second direction Y on the horizontal plane.

The third driving unit 476 may be a motor. The third driving unit 476 may move along the second rail 477 installed on a bottom surface of the housing 460. According to an embodiment, the second rail 477 may have its lengthwise direction horizontal to the first direction X. The third driving unit 476 may be forwardly and backwardly movable in the first direction X along the second rail 477. As the third driving unit 476 may be forwardly and backwardly movable in the first direction X, the housing 460 and the head nozzle 480 can be forwardly and backwardly movable in the first direction X on the horizontal plane.

The head nozzle 480 may have an objective lens and a barrel. The laser unit 500 to be described later may irradiate the laser to the target object through the head nozzle 480. For example, the laser oscillated from the laser unit 500 may be transferred to the head nozzle 480, and the head nozzle 480 may irradiate the received laser to the target object. The laser irradiated through the head nozzle 480 may have a generally flat-top shape when seen from above.

In addition, the imaging unit 700 to be described later may image the laser irradiated to the target object through the head nozzle 480. The imaging unit 700 may image a region irradiated with the laser through the head nozzle 480. For example, the imaging unit 700 may obtain an image of the target object including a region irradiated with the laser through the head nozzle 480. In addition, a lighting transmitted from the lighting unit 800 to be described later may be transmitted to the target object through the head nozzle 480. According to an embodiment, the target object may be the substrate M supported by the support unit 420. In addition, the target object may be a grid plate 493 provided in the first detection member 492 to be described later.

When seen from above, a center of the head nozzle 480 may move while drawing an arc. When seen from above, the center of the head nozzle 480 may pass through the center of the substrate M supported by the support unit 420. Also, when seen from above, the center of the head nozzle 480 may pass through a center CP of a region at which the second pattern P2 shown in FIG. 3 and FIG. 4 is formed.

The head nozzle 480 may be moved between a process position and a standby position by the moving unit 470. According to an embodiment, the process position may be a top side of the second pattern P2 formed on the substrate M supported by the support unit 420.

According to an embodiment, in the process position, the second pattern P2 may be heated by irradiating the laser on a specific region in which the second pattern P2 is formed. According to an embodiment, the process position may be a position corresponding to the top side of the substrate M supported by the support unit 420. According to an embodiment, when seen from above, the process position may be a position at which a center (CP, see FIG. 4) of a specific region at which the second pattern P2 of the substrate M supported by the support unit 420 overlaps a center of the head nozzle 480.

According to an embodiment, the standby position may be any one point in an outer region of the treating container 430. An inspection port 490 to be described later may be provided at the standby position. According to an embodiment, a maintenance operation of adjusting a state of the optical module 450 to a set condition may be performed in the standby position. A detailed description thereof will be described later.

The laser unit 500 irradiates the target object with the laser through the head nozzle 480. According to an embodiment, if the head nozzle 480 is positioned in the process position, the laser unit 500 irradiates the laser to the substrate M supported by the support unit 420 through the head nozzle 480. For example, if the head nozzle 480 is positioned in the process position, the laser unit 500 may irradiate the laser toward the center (CP, see FIG. 4) of a specific region at which the second pattern P2 is formed through the head nozzle 480. In addition, if the head nozzle 480 is positioned in the standby position, the laser unit 500 irradiates the laser through the head nozzle 480 toward the first detection member 492 and/or the second detection member 496, which will be described later.

The laser unit 500 may include an oscillation unit 520 and an expander 540. The oscillation unit 520 oscillates the laser. The oscillation unit 520 may oscillate the laser toward the expander 540. An output of the laser oscillated from the oscillation unit 520 may be changed according to a process requirement condition. A tilting member 522 may be installed in the oscillation unit 520. According to an embodiment, the tilting member 522 may be a motor. The tilting member 522 may rotate the oscillation unit 520 based on an axis. Accordingly, the tilting member 522 may change an oscillation direction of the laser oscillated by the oscillation unit 520.

The expander 540 may include a plurality of lenses which are not shown. The expander 540 may change a divergence angle of the laser oscillated from the oscillator 520 by changing an interval between the plurality of lenses. Accordingly, the expander 540 may change a diameter of the laser oscillated from the oscillator 520. For example, the expander 540 may expand or reduce the diameter of the laser oscillated from the oscillation unit 520. According to an embodiment, the expander 540 may be provided as a variable beam expander telescope (BET). The laser which diameter is changed in the expander 540 is transmitted to a bottom reflective plate 600.

The bottom reflective plate 600 is positioned on a moving path of the laser oscillated from the oscillation unit 520. According to an embodiment, the bottom reflective plate 600 may be positioned at a height corresponding to the oscillation unit 520 and the expander 540 when viewed from a side. In addition, the bottom reflective plate 600 may be positioned to overlap the head nozzle 480 when seen from above. In addition, the bottom reflective plate 600 may be positioned to overlap the top reflective plate 960 to be described later when seen from above. The bottom reflective plate 600 may be disposed below the top reflective plate 960. The bottom reflective plate 600 may be tilted at the same angle as the top reflective plate 960.

The bottom reflective plate 600 may change a moving path of the laser oscillated from the oscillation unit 520. The bottom reflective plate 600 may change the moving path of the laser passing through the expander 540. The bottom reflective plate 600 may change the moving path of the laser moving in the horizontal direction to a vertical downward direction. The laser which moving path is changed to the vertical downward direction by the bottom reflective plate 600 may be transmitted to the head nozzle 480. For example, the laser oscillated from the oscillation unit 520 may be irradiated to the second pattern P2 formed on the substrate M by sequentially passing through the expander 540, the bottom reflective plate 600, and the head nozzle 480.

The imaging unit 700 may image the laser irradiated to the target object. The imaging unit 700 may image a region irradiated with the laser. The imaging unit 700 may obtain an image of the target object including a region irradiated with the laser. According to an embodiment, the target object may be a substrate M supported by the support unit 420. In addition, the target object may be a grid plate 493 provided in the first detection member 492 to be described later.

The imaging unit 700 may be a camera module. For example, the imaging unit 700 may be a camera module which emits a visible light or a far infrared light. According to an embodiment, the imaging unit 700 may be a camera module in which a focus is automatically adjusted. An image acquired by the imaging unit 700 may include a video and/or a photo.

The imaging unit 700 may irradiate a visible light or the like toward the top reflective plate 960 to be described later. The visible light transmitted to the top reflective plate 960 is transmitted to the head nozzle 480, and the head nozzle 480 may irradiate the received visible light transmitted toward the target object.

The lighting unit 800 transmits the lighting to the target object so that the imaging unit 700 may easily obtain the image of the target object. The lighting transmitted by the lighting unit 800 may face the first reflective plate 920 to be described later.

The top reflective member 900 may include a first reflective plate 920, a second reflective plate 940, and a top reflective plate 960.

The first reflective plate 920 and the second reflective plate 940 change a direction of the light transmitted by the lighting unit 800. The first reflective plate 920 and the second reflective plate 940 may be installed at a height corresponding to each other. The first reflective plate 920 may reflect the light transmitted by the lighting unit 800 in a direction toward the second reflective plate 940. The second reflective plate 940 may reflect the light reflected from the first reflective plate 920 again in a direction toward the top reflective plate 960.

The top reflective plate 960 and the bottom reflective plate 600 may be disposed to overlap when seen from above. The top reflective plate 960 may be disposed above the bottom reflective plate 600. The top reflective plate 960 and the bottom reflective plate 600 may be tilted at the same angle as described above. The top reflective plate 960 changes an irradiation direction of the visible light irradiated from the imaging unit 700 and a lighting direction transmitted from the lighting unit 800 to the head nozzle 480. Accordingly, the irradiation direction of the visible light irradiated from the imaging unit 700 and the lighting direction transmitted from the lighting unit 800 may each be coaxial with the irradiation direction of the laser which moving path is changed in the direction toward the head nozzle 480 by the bottom reflective plate 600.

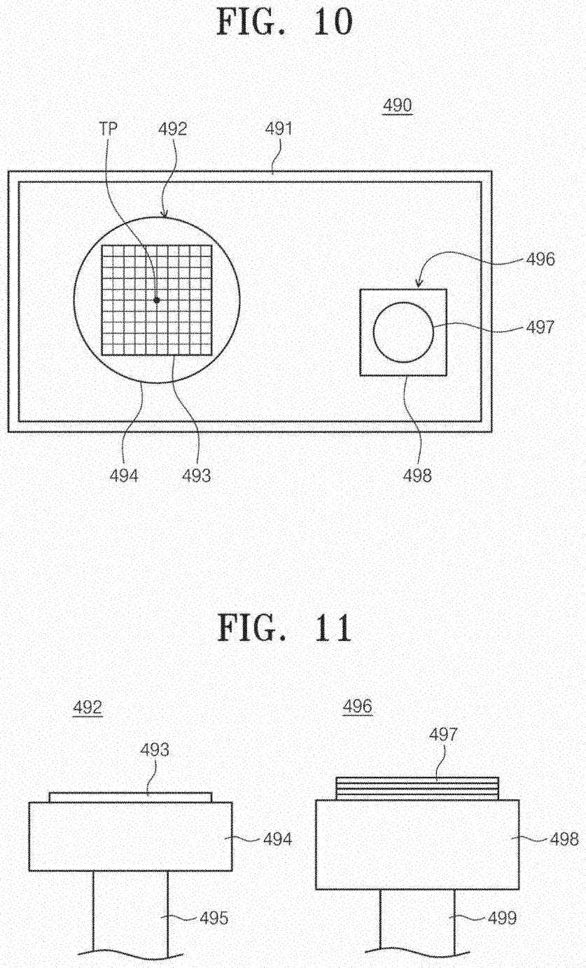

FIG. 10 schematically illustrates an inspection port according to an embodiment of FIG. 5 as seen from above. FIG. 11 schematically illustrates a state in which the first detection member and the second detection member are viewed from a side according to an embodiment of FIG. 5. Hereinafter, the inspection port according to an embodiment of the inventive concept will be described in detail with reference to FIG. 6, FIG. 10, and FIG. 11.

The inspection port 490 according to an embodiment is positioned in an outer region of the treating container 430. The inspection port 490 is provided at a standby position at which the optical module 450 is standing by. According to an embodiment, if the optical module 450 is positioned above the inspection port 490, the optical module 450 may be defined as being positioned in the standby position.

The state of the optical module 450 may be adjusted to a set condition at the inspection port 490. The set condition can be defined as a condition in which the laser irradiated to the substrate M can be uniformly irradiated when irradiating the laser to the substrate M supported by the support unit 420. In addition, the set condition may be defined as a condition in which the laser can be collectively irradiated to the second pattern P2 shown in FIG. 3 and FIG. 4 when irradiating the laser to the substrate M supported by the support unit 420. A detailed mechanism for this will be described later.

The inspection port 490 may include a housing 491, a first detection member 492, and a second detection member 496. The housing 491 may have an open top surface. A shape of the housing 491 may be transformed into various shapes with an open top surface. A first detection member 492 and a second detection member 496 may be positioned in the inner space of the housing 491.

The first detection member 492 may check the state of the optical module 450. For example, the first detection member 492 may check the state of the irradiation position of the laser irradiated by the optical module 450. In addition, the first detection member 492 may check the state of an imaging region of the optical module 450. According to an embodiment, the first detection member 492 may identify the irradiation position of the laser irradiated by the laser unit 500 shown in FIG. 8. In addition, the first detection member 492 may identify an imaging region of the imaging unit 700 shown in FIG. 8.

The first detection member 492 may include a grid plate 493, a body 494, and a support frame 495. A reference point TP may be displayed on a top surface of the grid plate 493. The reference point TP may function as a zero point for the optical module 450 to move to a region at which a specific pattern (e.g., the second pattern P2) is formed on the substrate M. A grid may be displayed on the top surface of the grid plate 493. The grid displayed on the grid plate 493 may confirm an error between a center of the irradiation position of the laser irradiated by the laser unit 500 illustrated in FIG. 8 and the reference point TP. In addition, the grid displayed on the grid plate 493 can confirm the error between a center of the imaging region of the imaging unit 700 shown in FIG. 8 and a center of the laser irradiation position irradiated by the laser unit 500.

A grid plate 493 may be coupled to the body 494. According to an embodiment, the grid plate 493 may be coupled to a top surface of the body 494. Alternatively, although not shown, an upper portion of the body 494 may have an open groove, and the grid plate 493 may be inserted into and fixed to the groove. A support frame 495 may be coupled to a bottom end of the body 494. The body 494 may be supported by the support frame 495. An end of the support frame 495 may be coupled to a bottom surface of the housing 491.

The second detection member 496 may detect the state of the optical module 450. According to an embodiment, the second detection member 496 may detect a profile of the laser irradiated by the laser unit 500 shown in FIG. 8.

The second detection member 496 may include an attenuation filter 497, a profiler 498, and a profiler frame 499. The attenuation filter 497 may be installed on the profiler 498. The attenuation filter 497 may reduce an intensity of the laser transmitted to the profiler 498. If the laser irradiated to the profiler 498 from the laser unit 500 shown in FIG. 8 has a high strength, the profile of the laser detected by the profiler 498 may be distorted. In addition, in this case, the profiler 498 may detect only a profile for a portion of the irradiated laser. Accordingly, the attenuation filter 497 reduces the intensity of the laser irradiated to the profiler 498, thereby minimizing the distortion of the laser profile detected by the profiler 498.

The profiler 498 detects the profile of the laser passing through the attenuation filter 497. The profiler 498 is irradiated from the laser unit 500 illustrated in FIG. 8, and can measure an intensity distribution of the laser passing through the attenuation filter 497 to detect the profile of the laser. The profiler 498 may be coupled to the profiler frame 499. The profiler 498 may be supported by the profiler frame 499. An end of the profiler frame 499 may be coupled to the bottom surface of the housing 491.

Although not shown, a height of the profiler 498, determined by the profiler frame 499, may be the same as the substrate M supported by the support unit 420. For example, a height from the bottom surface of the housing 460 shown in FIG. 5 to the top surface of the profiler 498 may be the same as a height from the bottom surface of the housing 460 to the top surface of the substrate M supported by the support unit 420.

This is to match a distance between the target object and the head nozzle 480 since the laser is irradiated from the head nozzle 480. Specifically, the laser profile may be changed according to an irradiation height of the laser irradiated to the profiler 498 through the head nozzle 480. As will be described later, a height between the head nozzle 480 and the profiler 498 can be determined by adjusting the laser profile on a top side of the second detection member 496, and if the laser is irradiated to the substrate M supported by the support unit 420, a changing of the profile of the adjusted laser may be prevented by a height change between the head nozzle 480 and the top surface of the substrate.

In the above-described embodiment, the case in which the second detection member 496 has the attenuation filter 497 has been described as an example, but the inventive concept is not limited thereto. For example, the second detection member 496 may not include the attenuation filter 497. In this case, an intensity of the laser irradiated by the laser unit 500 shown in FIG. 8 may be transmitted to the profiler 498 without changing the intensity. Hereinafter, for convenience of understanding, a case in which the second detection member 496 includes an attenuation filter 497 will be described as an example.

Hereinafter, a substrate treating method according to an embodiment of the inventive concept will be described in detail. The substrate treating method described below may be performed in the chamber 400 according to an embodiment described with reference to FIG. 2 and FIG. 5 to FIG. 11. In addition, the controller 30 may control the components of the chamber 400 so as to perform the substrate treating method described below.

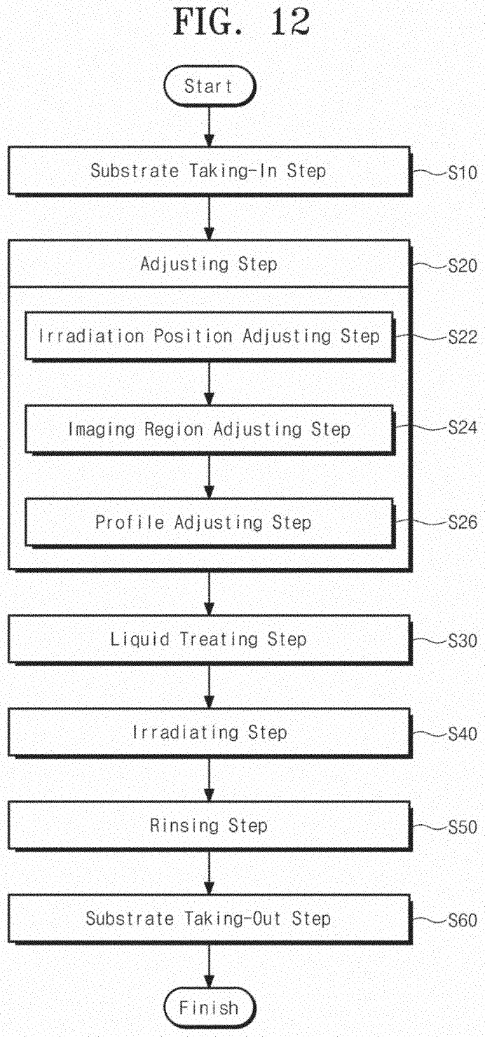

FIG. 12 is a flowchart of a substrate treating method according to an embodiment of the inventive concept. Referring to FIG. 12, the substrate treating method according to an embodiment of the inventive concept may include a substrate taking-in step S10, an adjustment step S20, a liquid treating step S30, an irradiation step S40, a rinsing step S50, and a substrate taking-out step S60.

In the substrate taking-in step S10, the substrate M is taken into the inner space 412 of the housing 410. For example, in the substrate taking-in step S10, the opening (not shown) formed in the housing 410 may be opened by a door (not shown). The substrate M may be taken into the inner space 412 through an opening (not shown) which is open. In the substrate taking-in step S10, the transfer robot 320 may mount the substrate M on the support unit 420. Before the transfer robot 320 mounts the substrate M on the support unit 420, the lifting/lowering member 436 may downwardly move the treating container 430. If the transfer robot 320 mounts the substrate M on the support unit 420, the lifting/lowering member 436 may upwardly move the treating container 430.

The adjustment step S20 may be performed before treating the substrate M. For example, the adjustment step S20 may be performed before the liquid treatment is performed on the substrate M. In addition, the adjustment step S20 may be performed before the substrate M is heated. The adjustment step S20 may be performed while the optical module 450 is in the standby position before the optical module 450 moves to the process position, which is a top side of the support unit 420. The adjustment step S20 may be performed at an inspection port 490 provided at the standby position where the optical module 450 is standing by. That is, the adjustment step S20 may be performed while the optical module 450 is positioned above the inspection port 490.

In the adjustment step S20, the state of the optical module 450 is adjusted prior to treating the substrate M. In the adjustment step S20, the state of the optical module 450 may be adjusted as a set condition.

As described above, the set condition may be a condition in which the laser irradiated to the substrate M may be uniformly irradiated if the substrate M is heat-treated by irradiating the substrate M supported by the support unit 420. In addition, the set condition may be a condition in which the laser may be collectively irradiated to the second pattern P2 shown in FIG. 3 and FIG. 4 if the substrate M is heat-treated by irradiating the substrate M supported by the support unit 420.

The adjustment step S20 may include an irradiation position adjustment step S22, an imaging region adjustment step S24, and a profile adjustment step S26.

In the irradiation position adjustment step S22, the irradiation position of the laser irradiated to a target object in the laser unit 500 may be adjusted to the set condition. In addition, in the imaging region adjustment step S24, the imaging region of the imaging unit 700 may be adjusted under the set condition. In addition, in the profile adjustment step S26, the profile of the laser irradiated from the laser unit 500 may be adjusted to the set condition.

The irradiation position adjustment step S22 and the imaging region adjustment step S24 are performed at the inspection port 490 provided at the standby position. The irradiation position adjustment step S22 and the imaging region adjustment step S24 according to an embodiment are performed by the first detection member 492. For example, the irradiation position adjustment step S22 and the imaging region adjustment step S24 may be performed at a position at which the head nozzle 480 and the grid plate 493 overlap each other when seen from above.

The profile adjustment step S26 is performed at the inspection port 490 provided at the standby position. The profile adjustment step S26 according to an embodiment is performed in the second detection member 496. For example, the profile adjustment step S26 may be performed at a position at which the head nozzle 480 and the attenuation filter 497 overlap each other when seen from above.

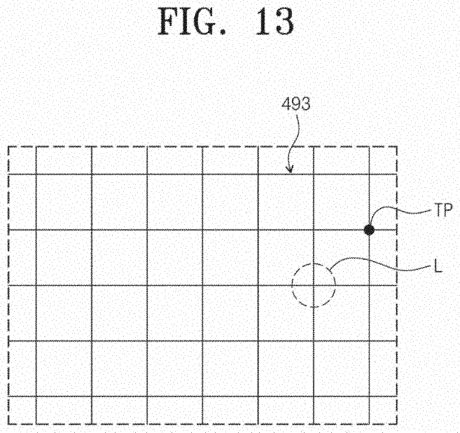

Hereinafter, an irradiation position adjustment step S22 according to an embodiment of the inventive concept will be described with reference to FIG. 13 to FIG. 15, an imaging region adjustment step S24 according to an embodiment of the inventive concept will be described with reference to FIG. 16 to FIG. 18, and a profile adjustment step S26 according to an embodiment of the inventive concept will be described.

FIG. 13 schematically illustrates a state in which an error between the irradiation position of the laser irradiated with the first detection member and the reference point is confirmed.

As shown in FIG. 13, the irradiation position and reference point TP of the laser L irradiated to the grid plate 493 can be captured by the imaging unit 700. Accordingly, the imaging unit 700 may obtain an image including the laser L and the reference point TP irradiated to the grid plate 493. The laser L irradiated to the grid plate 493 through the head nozzle 480 may deviate from the reference point TP. For example, in the image acquired by the imaging unit 700, a center of the laser L irradiated to the grid plate 493 may be positioned below the left side from the reference point TP. In this way, if the center of the laser L irradiated to the grid plate 493 does not match the reference point TP, an irradiation position adjustment step S22 is performed.

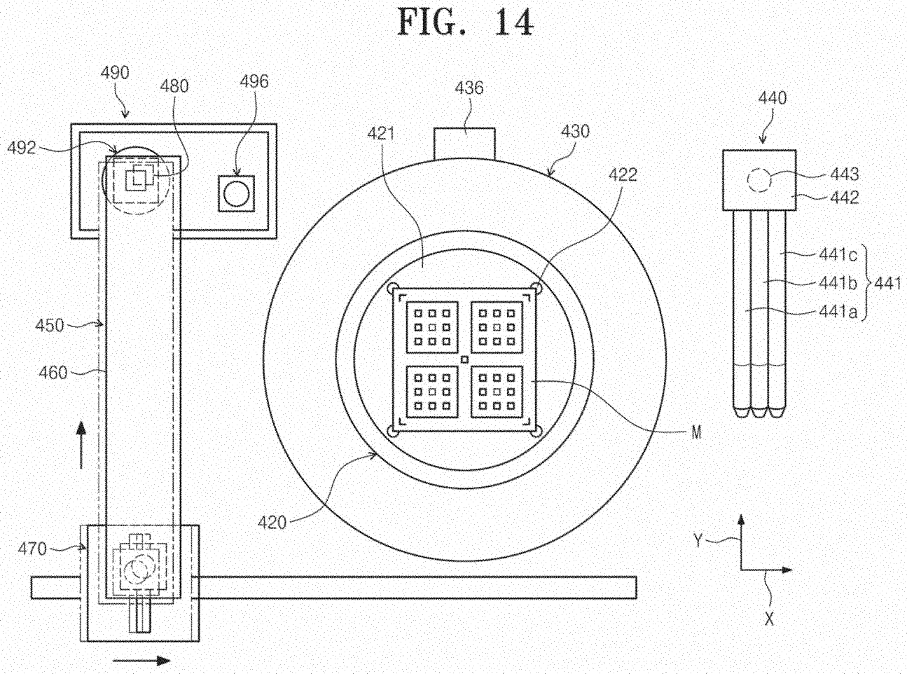

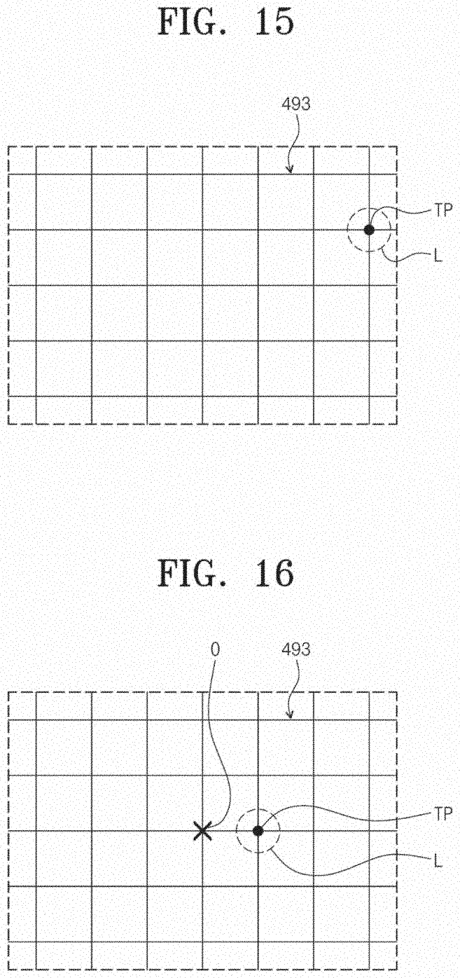

FIG. 14 schematically illustrates the optical module performing the irradiation position adjustment step according to an embodiment of FIG. 12 after an error between the irradiation position and the reference point of the laser is confirmed. FIG. 15 schematically illustrates a state in which the irradiation position of the laser irradiated with the first detection member is adjusted to the reference point after the irradiation position adjustment step of FIG. 14 is performed.

Referring to FIG. 14, in the irradiation position adjustment step S22, the optical module 450 is moved to match the center of the laser L irradiated to the grid plate 493 with the reference point TP. In the irradiation position adjustment step S22, the moving unit 470 moves the optical module 450. For example, in the irradiation position adjustment step S22, the optical module 450 may forwardly and backwardly move in the second direction Y and the first direction X by the second driving unit 474 and the third driving unit 476 shown in FIG. 7. Accordingly, the head nozzle 480 may move in the first direction X and/or the second direction Y on the horizontal plane.

If the head nozzle 480 is moved on the horizontal plane, the irradiation position of the laser irradiated through the head nozzle 480 can be changed on the grid plate 493. For example, since the irradiation position of the laser irradiated to the grid plate 493 in FIG. 13 is lower than the reference point TP when seen from above, the optical module 450 may move in the direction of the right side and the upper side when seen from above as shown in FIG. 14.

The optical module 450 may move on a horizontal plane until the irradiation center of the laser and the reference point TP coincide with each other. The imaging unit 700 may continuously image the laser L and the reference point TP irradiated to the grid plate 493 while the optical module 450 moves on the horizontal plane. As shown in FIG. 15, if the irradiation position of the laser L irradiated to the grid plate 493 matches the reference point TP in the image acquired by the imaging unit 700, the optical module 450 stops moving on the horizontal plane. Accordingly, the irradiation position of the laser L irradiated from the optical module 450 may be adjusted to the reference point TP. If the irradiation position of the laser L is adjusted to the reference point TP, the irradiation position of the laser L is adjusted to the set condition.

The reference point TP functions as a zero point for the optical module 450 to move to a specific area in which the second pattern P2 is formed on the substrate M. Specifically, the reference point TP may function as a zero point for the head nozzle 480 to move to the center (CP, see FIG. 4) of a specific region at which the second pattern P2 formed on the substrate M is formed. For example, a distance from the reference point TP to the second pattern P2 may be stored in the controller 30 as a preset value. If the center of the laser is adjusted to the reference point TP, the head nozzle 480 may move by a predetermined distance stored in the controller 30 following the taken-in substrate M, to accurately move upwardly of the center (CP, see FIG. 4) of a specific region at which the second patterns P2 are formed. That is, the laser which center position is adjusted to the reference point TP may accurately move to the center CP of the region at which the second pattern P2 is formed. Accordingly, by performing the irradiation position adjustment step S22 according to an embodiment, the laser may be accurately irradiated to the second pattern P2.

FIG. 16 schematically illustrates an error confirmed between the irradiation position of the laser irradiated to the first detection member and an imaging region of the imaging unit.

As shown in FIG. 16, the imaging unit 700 acquires an image of the grid plate 493 including an irradiation position of the laser L irradiated to the grid plate 493 by using the top surface of the grid plate 493 as an imaging region. According to an embodiment, the imaging unit 700 acquires the image of the grid plate 493 with the center of the laser L irradiated to the grid plate 493 adjusted to the reference point TP after the irradiation position adjustment step S22 is performed.

As shown in FIG. 16, the center O of the imaging region may deviate from the center of the laser L. For example, the center O of the imaging region may be positioned on the left side of the reference point TP corresponding to the center of the laser L. As described above, if the center O of the imaging region does not match the center of the laser L, the imaging region adjustment step S24 may be performed.

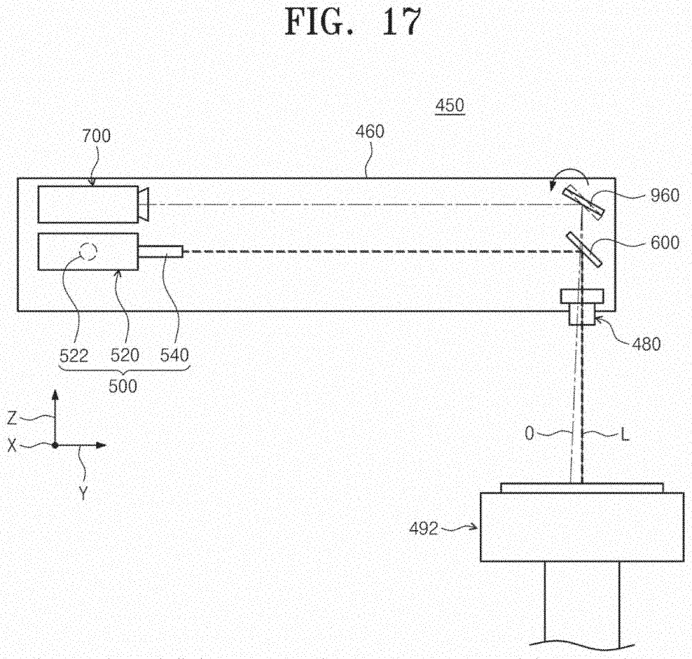

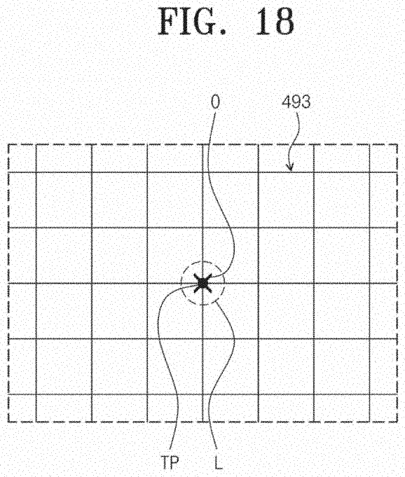

FIG. 17 schematically illustrates the optical module performing an imaging region adjustment step according to an embodiment of FIG. 12 after an error between an irradiation position of the laser and the imaging region is confirmed. FIG. 18 schematically illustrates a state in which an imaging region is adjusted to the irradiation position of the laser irradiated with the first detection member after the imaging region adjustment step of FIG. 17 is performed.

In the imaging region adjustment step S24, a tilting angle of the lens provided in the imaging path may be adjusted so that the imaging region of the imaging unit 700 coincides with a center of the laser L irradiated to the grid plate 493. For example, referring to FIG. 8, FIG. 9, and FIG. 17, the top reflective plate 960 and a head nozzle 480 may be positioned in an imaging path of the imaging unit 700. In the imaging region adjustment step S24 according to an embodiment, the imaging region of the imaging unit 700 for the grid plate 493 may be adjusted by adjusting the tilting angle of the top reflective plate 960. The tilting angle of the top reflective plate 960 may be adjusted based on a first direction X, a second direction Y, and a third direction Z. For example, the top reflective plate 960 may be tilted with the first direction X as an axis so that a center O of the imaging region and the irradiation direction of the laser are coaxial with each other.

By adjusting the tilting angle of the top reflective plate 960, the position of the center O of the imaging region on the grid plate 493 can be moved, as illustrated in FIG. 18. The center O of the imaging region in which the position is moved may coincide with the center of the laser L. In addition, the center O of the imaging region in which the position is moved may coincide with the reference point TP. If the center O of the imaging region coincides with the center of the laser L and the reference point TP, the imaging region of the imaging unit 700 is adjusted under a set condition.

The imaging region adjustment step S24 according to an embodiment may be performed after the irradiation position adjustment step S22. Accordingly, after the irradiation position of the laser is adjusted to the set condition, the center of the imaging region is adjusted to match the center of the irradiated laser, so that the state of the laser irradiated to the target object (e.g., substrate M, etc.) can be precisely monitored.

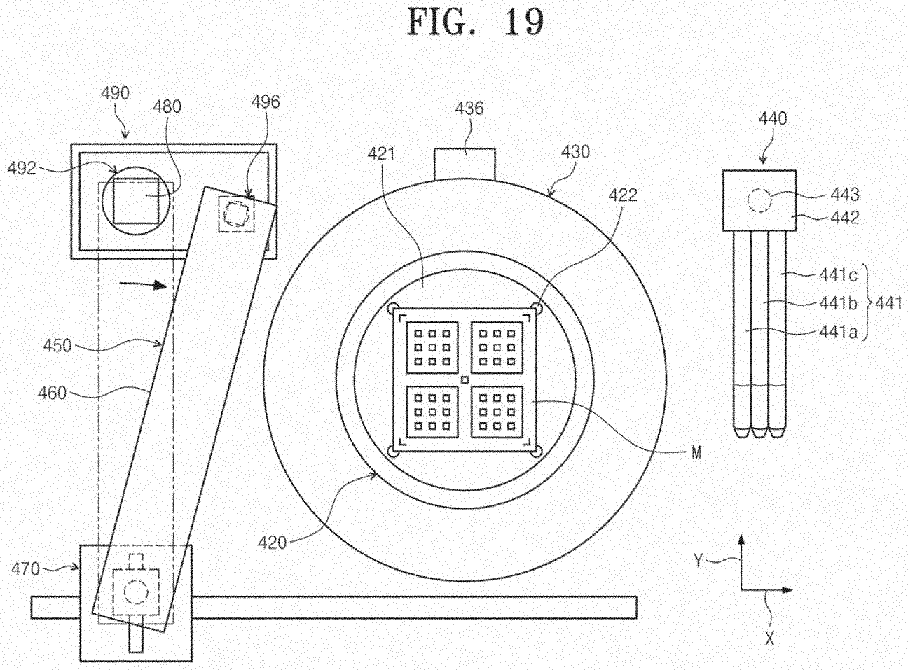

FIG. 19 illustrates above that the optical module moves from the first detection member to the second detection member after both the irradiation position adjustment step and the imaging region adjustment step of FIG. 12 are performed.

After the irradiation position adjustment step S22 and the imaging region adjustment step S24 are completed, the optical module 450 may move from the top side of the first detection member 492 to the top side of the second detection member 496. For example, after the irradiation position adjustment step S22 and the imaging region adjustment step S24 are completed, the head nozzle 480 may move from a position overlapping the grid plate 493 when seen from above to a position overlapping the attenuation filter 497. If the head nozzle 480 is positioned above the attenuation filter 497, the laser unit 500 irradiates the laser toward the attenuation filter 497. An intensity of the laser may decrease while passing through the attenuation filter 497. The laser passing through the attenuation filter 497 is transferred to the profiler 498. The profiler 498 may detect the profile of the received laser.

The reference profile data of the laser having the set condition may be stored in the controller 30. As described above, the set condition may be a condition in which the laser may be collectively irradiated to the second pattern P2 shown in FIG. 3 and FIG. 4. In addition, the set condition may be a condition in which the laser may be uniformly irradiated to the second pattern P2. This has been described above.

In addition, the reference profile data may have a reference range. The reference range may contain a diameter range of the laser, a steepness range of the laser, or a uniformity range of the laser. If the profile of the laser detected by the profiler 498 does not satisfy the reference range, the profile adjustment step S26 may be performed. In the profile adjustment step S26 according to an embodiment, if the profile of the laser detected by profiler 498 does not satisfy the diameter range of the laser, a laser steepness range, and a laser uniformity range, at least one of the diameter, the steepness, and the uniformity of the laser which is irradiated may be adjusted.

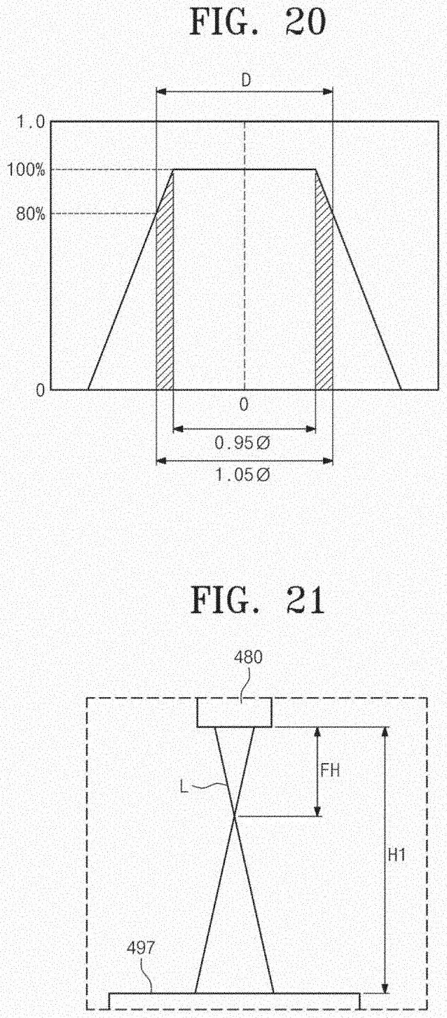

FIG. 20 is a graph illustrating a diameter range of a profile reference range of a laser having a set condition. Hereinafter, profiles of the laser are schematically illustrated for a convenience of understanding. The profile of the illustrated laser may have a gaussian distribution. In addition, the profile of the illustrated laser may have a flat distribution.

In order for the laser to be collectively irradiated to the second pattern P2 illustrated in FIG. 3 and FIG. 4, the diameter of the laser must correspond to a specific region at which the second pattern P2 is formed. Specifically, if the irradiation center of the laser coincides with the center of a specific region (CP, see FIG. 4) at which the second pattern P2 is formed, the diameter of the laser must correspond to the specific region at which the second pattern P2 is formed to collectively irradiate the second patterns P2. For example, if the irradiation center of the laser coincides with the center CP of the region at which the second pattern P2 is formed, and if the diameter of the irradiated laser is less than a maximum length (Φ) of the second pattern P2 formed in a specific region of the substrate M, the laser may not be irradiated to some second patterns P2.

The controller 30 may store a data (hereinafter, a diameter range) of the diameter range among a reference range of the laser profile. The diameter range may be defined by Equation 1 as follows.

0.95ø<D<<1.05ø [Equation 1]

The Φ expressed in Equation 1 above may mean the maximum length (Φ) of the second pattern P2 described with reference to FIG. 4. That is, the diameter range may be between 0.95 times the maximum length (Φ) of the second pattern P2 and 1.05 times the maximum length (Φ) of the second pattern P2.

D expressed in Equation 1 above refers to an estimated diameter of the laser measured by the second detection member 496. An estimated diameter D may mean the estimated diameter of the laser irradiated to the second detection member 496. Specifically, the estimated diameter D is defined as a length of a horizontal axis corresponding to a 80% intensity value in the laser profile measured by the second detection member 496, as shown in FIG. 20. That is, the diameter of the laser having the intensity of the lower 80% may be defined as the estimated diameter D.

If the estimated diameter D of the laser measured by the profiler 498 does not satisfy the diameter range of Equation 1, the controller 30 may determine that a diameter of the laser has not been uniformly irradiated to the second pattern P2 and may perform the profile adjustment step S26.

In contrast, if the estimated diameter D of the laser measured by the profiler 498 satisfies the diameter range of Equation 1, the controller 30 may determine that the diameter of the irradiated laser is in a normal state. That is, the controller 30 may determine that the laser diameter satisfies the set condition.

Hereinafter, referring to FIG. 21 to FIG. 24, an example in which the profile adjustment step S26 is performed will be described if the estimated diameter D does not satisfy the diameter range.

FIG. 21 is a front view of an optical module irradiating a laser to the second detection member.

Referring to FIG. 21, the head nozzle 480 is positioned above the attenuation filter 497. The head nozzle 480 is positioned at a first height H1 from the attenuation filter 497. According to an embodiment, a bottom end of the head nozzle 480 may be positioned at a first height H1 from a top end of the attenuation filter 497.

The head nozzle 480 irradiates the laser L toward the attenuation filter 497. The laser L irradiated by the head nozzle 480 may have a flat-top shape when seen from above. The laser L irradiated toward the attenuation filter 497 is transferred to the profiler 498. The profiler 498 detects the profile of the laser L.

The laser L irradiated by the head nozzle 480 has a focal length FH. The focal length FH may be defined as a vertical distance from a bottom end of the head nozzle 480 to a focal point of the laser L. If a position of the lenses provided in the expander 540 are not changed, a value of the focal length FH is fixed. In addition, if the tilting angle of the bottom reflective plate 600 is not changed, the value of the focal length FH is fixed. In addition, if the setting of the objective lens included in the head nozzle 480 is not changed, the value of the focal length FH is fixed. Hereinafter, for a convenience of understanding, it will be described as an example that the focal length FH of the laser L irradiated by the head nozzle 480 has a fixed value.

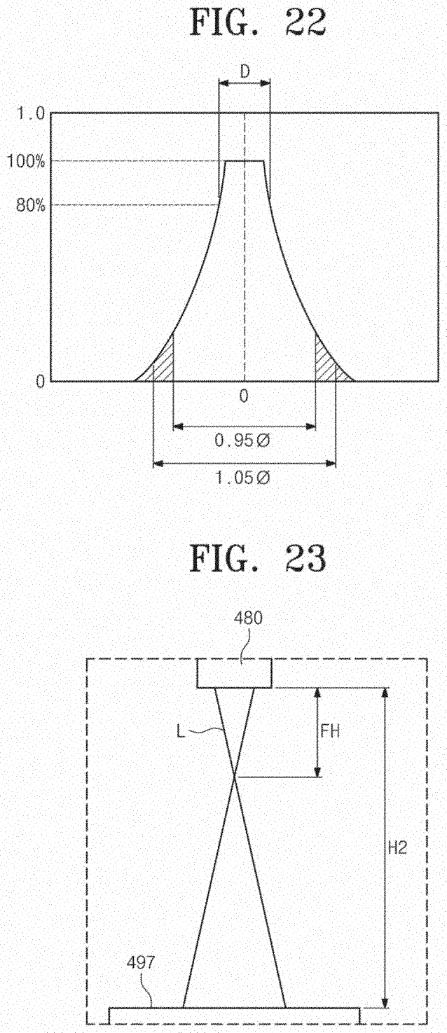

FIG. 22 is a graph schematically illustrating a state in which a profile of a laser measured in the second measuring member of FIG. 21 does not satisfy a diameter range.

The estimated diameter D of the laser measured by the profiler 498 may not be included in the diameter range of Equation 1. For example, as shown in FIG. 22, the estimated diameter D of the detected laser may be less than 0.95 times the maximum length (Φ) of the second pattern P2. In this case, since the diameter of the laser irradiated from the head nozzle 480 cannot collectively etch the second patterns P2 formed on the substrate M, the profile adjustment step S26 is performed.

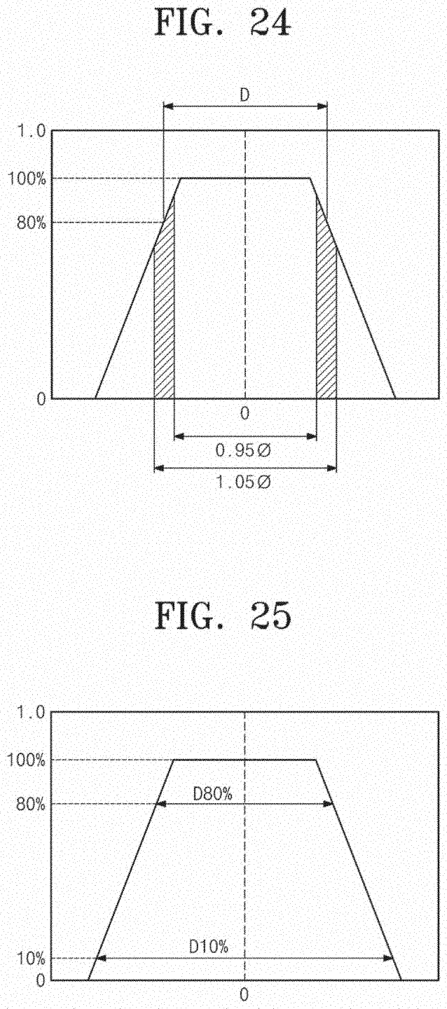

FIG. 23 is an enlarged view schematically showing that the optical module irradiates the laser with the second detection member after performing the profile adjustment step of FIG. 12 by moving the optical module. FIG. 24 is a graph schematically illustrating a state in which the profile of a laser measured in the second detection member of FIG. 23 satisfies the diameter range.

In the profile adjustment step S26, the head nozzle 480 is moved to adjust the diameter of the laser. For example, as described above, the position of the head nozzle 480 may be changed as the optical module 450 illustrated in FIG. 5 moves. In the profile adjustment step S26, the controller 30 may control the first driving unit 471 to move the housing 460 in the vertical direction. As the housing 460 moves up and down, a height of the head nozzle 480 inserted into the housing 460 may be changed.

If the estimated diameter D of the detected laser is less than 0.95 times the maximum length (Φ) of the second pattern P2, the head nozzle 480 may upwardly move from the attenuation filter 497. While the head nozzle 480 upwardly moves from the attenuation filter 497, the head nozzle 480 irradiates the laser L toward the attenuation filter 497.

As described above, if the head nozzle 480 upwardly moves, the focal length FH of the laser L irradiated from the head nozzle 480 does not change, so the diameter of the laser irradiated to the attenuation filter 497 and the profiler 498 may increase. Accordingly, the estimated diameter D of the laser measured by the profiler 498 may also increase.

The profiler 498 detects the profile of the laser L continuously transmitted from the attenuation filter 497. If the estimated diameter D of the laser L measured by the profiler 498 is included in the diameter range of Equation 1 above, the head nozzle 480 stops moving in the upward direction.

FIG. 23 shows that the head nozzle 480 moves by a first distance in the upward direction, and the bottom end of the head nozzle 480 is positioned at the second height H2 from the top end of the attenuation filter 497. The second height H2 may be greater than the first height H1 shown in FIG. 21.

If the head nozzle 480 moves by the first distance in the upward direction, if the estimated diameter D of the laser measured by the profiler 498 is included in the diameter range of Equation 1 as shown in FIG. 24, the head nozzle 480 stops moving in the upward direction. If the estimated diameter D of the laser measured by the profiler 498 is included in the diameter range of Equation 1, the controller 30 may determine that the diameter of the laser irradiated from the head nozzle 480 is suitable for collectively heating the second pattern P2. That is, the controller 30 may determine that the laser diameter satisfies the set condition.

According to an embodiment of the inventive concept, after performing the profile adjustment step S26 of adjusting the laser diameter, the diameter of the laser irradiated from the head nozzle 480 may correspond to a maximum length (see FIG. 4) of the second pattern P2 formed in a specific region of the substrate M. Accordingly, the second patterns P2 formed in the specific region of the substrate M may be collectively irradiated by the laser.

FIG. 25 is a graph illustrating a steepness range among a profile reference range of a laser having a set condition.

The laser should uniformly irradiate the second patterns P2 (see FIG. 4) formed in a specific region of the substrate M. In order for the laser to be uniformly irradiated to the second patterns P2, the steepness of the laser is important. The steepness may mean an inclination of the detected laser profile.

For example, if the steepness of the detected profile is infinite (e.g., if the profile of the detected laser has a square shape), the laser irradiated to the target object has the same intensity throughout the irradiation area of the target object.

For example, if the steepness of the detected profile has a value of the first steepness which is less than infinity, a central region of the laser irradiation area at which the laser is irradiated to the target object has a relatively lower intensity than if the steepness is infinite. In addition, an edge region of the laser irradiation region in which the laser is irradiated to the target object may have a lower intensity than the laser intensity of the central region.

In addition, if the steepness of the detected profile has a value of a second steepness that is smaller than the first steepness, the central area of the laser irradiation region at which the laser is irradiated to the target object may have a relatively lower intensity than the first steepness value. This results from the same phenomenon as a sum of light densities of the laser in the detected profile.

Accordingly, a data on a steepness range (hereinafter, a steepness range) among the reference ranges of the profile of the laser may be stored in the controller 30. The steepness range may be defined by Equation 2 as follows.

$$\frac{\vert D 10 \% - D 80 \% \vert}{D 80 \%} \times 100 < 10 \% \qquad [ Equation 2 ]$$

As shown in FIG. 25, D10% which is expressed in Equation 2 above is defined as a length of the horizontal axis corresponding to an intensity value of the lower 10% calculated from the profile of the laser measured by the second detection member 496. That is, D10% may be defined as the diameter of the laser having an intensity of the lower 10%. In addition, D80% expressed in Equation 2 above is defined as the length of the horizontal axis corresponding to the lower 80% intensity value calculated from the profile of the laser measured by the second detection member 496. That is, D80% may be defined as the diameter of the laser having the intensity of the lower 80%. In other words, the smaller the difference between the diameter of the laser with the lower 80% intensity calculated from the laser profile and the diameter of the laser with the lower 10% intensity, the more evenly the laser can be irradiated to the target object.

According to an embodiment of the inventive concept, if the

$$\frac{\vert D 10 \% - D 80 \% \vert}{D 80 \%} \times 100$$

value measured in the laser profile is within the range of 10%, the controller 30 may determine that the steepness of the laser to be irradiated is in a normal state. That is, the controller 30 may determine that the steepness of the laser satisfies the set condition.

In contrast, if the

$$\frac{\vert D 10 \% - D 80 \% \vert}{D 80 \%} \times 100$$

value detected in the laser profile is outside the 10% range, the controller 30 may determine that the irradiated laser is not uniformly irradiated to the second pattern P2 and perform the profile adjustment step S26.

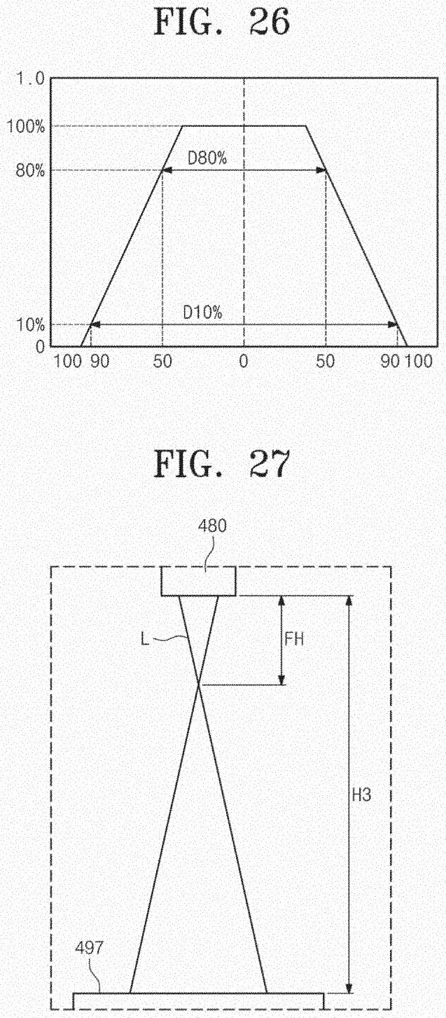

Hereinafter, an example in which the profile adjustment step S26 is performed will be described with reference to FIG. 26 to FIG. 28 if the profile of the detected laser does not satisfy the steepness range.

In FIG. 23, after the diameter of the laser L irradiated from the head nozzle 480 is adjusted to the diameter range, the optical module 450 re-irradiates the laser L to the attenuation filter 497 through the head nozzle 480. In this case, the height of the bottom end of the head nozzle 480 and the top end of the attenuation filter 497 may be maintained at a second height H2 as illustrated in FIG. 23.

FIG. 26 is a graph schematically illustrating a state in which a profile of a laser measured in the second detection member of FIG. 23 does not satisfy a steepness range.

The profiler 498 detects the profile of the irradiated laser. According to an embodiment, the controller 30 may determine whether the profile of the laser detected by the profiler 498 satisfies the steepness range.

As illustrated in FIG. 26, the profile of the laser detected by the profiler 498 may have a D10% value of 180 and a D80% value of 100. In this case, the controller 30 may determine that the steepness of the irradiated laser is 44.4% based on Equation 2. Accordingly, the controller 30 may perform the profile adjustment step S26 by determining that the profile detected from the irradiated laser L does not satisfy the steepness range.

It is preferable that the profile adjustment step S26 of adjusting the steepness of the laser precedes the profile adjustment step S26 of adjusting the diameter of the laser. This is because the steepness of the laser rapidly changes according to a change in a fine distance between the target object and the head nozzle 480 to which the laser is irradiated. Accordingly, it is desirable to perform the profile adjustment step S26 to adjust the steepness by moving the head nozzle 480 up and down to adjust the laser diameter to the diameter range, and then moving the head nozzle 480 up and down by the fine distance as described later. However, the inventive concept is not limited thereto, and after adjusting the steepness of the laser, the diameter of the laser may be adjusted.

In the profile adjustment step S26 of adjusting the steepness, the steepness of the laser may be adjusted by moving the optical module 450 illustrated in FIG. 5. For example, in the profile adjustment step S26 of adjusting the steepness, the controller 30 may control the first driving unit 471 to move the housing 460 in the vertical direction. As the housing 460 moves up and down, the height of the head nozzle 480 inserted into the housing 460 may be changed.

In the profile adjustment step S26 of adjusting the steepness, the head nozzle 480 may move up and down by a second distance. The second distance may have a value smaller than a first distance which is a moving distance of the head nozzle 480 in the profile adjustment step S26 of adjusting the diameter. For example, the second distance may be a distance that may move up and down within a range in which an estimated diameter of the laser irradiated from the head nozzle 480 satisfies a diameter range of 0.95Φ to 1.05Φ. This is because, as described above, the steepness of the laser rapidly changes according to the change in the fine distance between the target object and the head nozzle 480. That is, according to an embodiment of the inventive concept, the steepness of the laser may be adjusted without an adjusted diameter deviating from the diameter within the reference range.

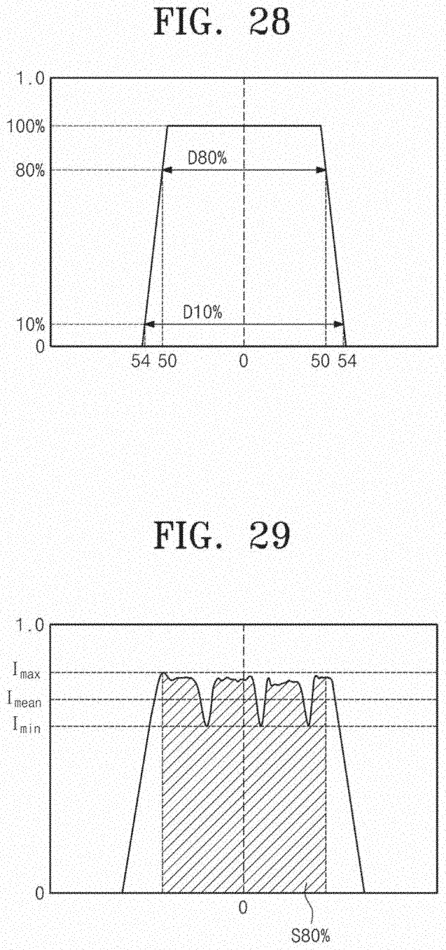

FIG. 27 is an enlarged view schematically showing that the optical module irradiates the laser to the second detection member after performing the profile adjustment step of FIG. 12 by moving the optical module. FIG. 28 is a graph schematically illustrating a state in which the profile of the laser measured in the second detection member of FIG. 27 satisfies the steepness range.

As shown in FIG. 27, the head nozzle 480 may move by a second distance in the upward direction. In this case, a bottom end of the head nozzle 480 may be positioned at a third height H3 from a top end of the attenuation filter 497. The third height H3 may be a value relatively larger than the second height H2 shown in FIG. 23.

As shown in FIG. 28, when it is determined that the profile of the laser detected by the second detection member 496 has an 8% steepness while the head nozzle 480 moves to the third height H3, the optical module 450 stops a vertical movement. In this case, the controller 30 may determine that the steepness of the laser irradiated from the head nozzle 480 is in a state suitable for uniformly heating the second pattern P2. That is, the controller 30 may determine that the steepness of the laser satisfies the set condition.

After performing the profile adjustment step S26 of adjusting the steepness of the laser, the laser irradiated from the head nozzle 480 may have a uniform strength. Accordingly, the laser having a uniform strength may be irradiated to the second patterns P2 (see FIG. 4) formed in the specific region of the substrate M. Accordingly, the second patterns P2 may be uniformly heated by a laser and uniformly etched.

Although the above example illustrates that the head nozzle 480 upwardly moves to perform the profile adjustment step S26 for the steepness, it is natural that the head nozzle 480 downwardly moves to perform the profile adjustment step S26 for the steepness according to the profile of the laser detected by the second detection member 496.

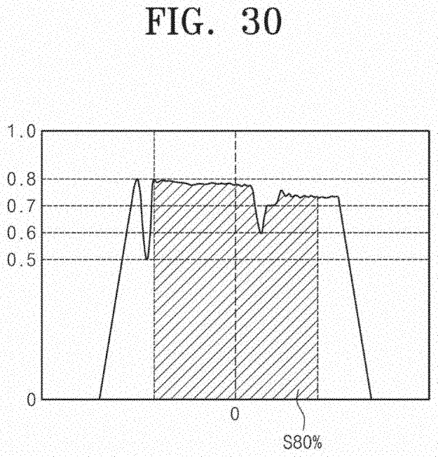

FIG. 29 is a graph illustrating a uniformity range among a profile reference range of the laser having a set condition.

The laser should be uniformly irradiated to a region at which the second patterns P2 (see FIG. 4) are formed. In order for the laser to be uniformly irradiated to the second pattern P2, a uniformity of the laser is important. The uniformity is associated with a clipping occurring at a top end of a detected laser profile. For example, as the clipping occurs more at the top end of the detected laser profile, the uniformity of the laser decreases. If the uniformity of the laser decreases, an intensity per unit area of the laser irradiated to the target object may not be constant. Accordingly, a data (hereinafter, a uniformity range) of a uniformity range among the profile reference ranges of the laser may be stored in the controller 30. The uniformity range may be defined by Equation 3 as follows.

$$\frac{I max - I min}{2 I mean} \times 100 < 10 \% \qquad [ Equation 3 ]$$

Imax which is expressed in Equation 3 above means a maximum intensity in a 80% region of the detected profile, as illustrated in FIG. 29. That is, Imax may mean the highest intensity value within 80% of the profile measured by the second detection member 496. In addition, Imin expressed in Equation 3 above means a minimum intensity in the 80% region of the detected profile. That is, Imin may mean the smallest intensity value within 80% of the profile measured by the second detection member 496. In addition, Imean expressed in Equation 3 above means the average values of Imax and Imin.

For example, as shown in FIG. 30, the controller 30 may determine an Imax value of 0.8 within 80% of the detected profile. A value of 0.5 outside the 80% region of the detected profile cannot be an Imin value. Accordingly, the controller 30 may determine 0.6 as the Imin value, which is the smallest intensity value within 80% of the detected profile. In addition, the controller 30 may determine that the Imean value is 0.7.

The controller 30 determines Imax, Imin, and Imean values in the profile of the laser detected by the profiler 498, and if the

$$\frac{I max - I min}{2 Imean} \times 100$$

value is less than 10%, the irradiated laser satisfies the uniformity range. For example, the smaller the interval between Imax and Imin of the detected profile (the smaller the

$$\frac{I max - I min}{2 Imean} \times 100$$

value of the profile), the less clipping occurs on the top end of the laser. Accordingly, the controller 30 may determine that the uniformity of the irradiated laser is good. That is, the controller 30 may determine that the uniformity of the laser satisfies the set condition.

If the laser satisfies the uniformity range, the laser may be uniformly irradiated to the second patterns P2 shown in FIG. 4.

In contrast, if the

$$\frac{I max - I min}{2 Imean} \times 100$$

value determined in the profile of the laser detected by the profiler 498 is 10% or more, the irradiated laser is determined not to satisfy the uniformity range. For example, the larger a gap between Imax and Imin of the detected profile (the larger the

$$\frac{I max - I min}{2 Imean} \times 100$$

value of the profile), the more clipping is generated on the top end of the laser, which can be interpreted as having a poor laser uniformity. Accordingly, the controller 30 may determine that the uniformity of the irradiated laser is not good. If the laser does not satisfy the uniformity range, the laser may not be uniformly irradiated to the second patterns P2 shown in FIG. 4. In this case, the controller 30 may determine that a problem has occurred in the components included in the optical module 450 shown in FIG. 8, and may generate an interlock using an alarm or the like. Selectively, the controller 30 may adjust a position and/or a tilting angle of the components 480, 520, 522, 540, 600 existing on the optical path of the laser illustrated in FIG. 8.

Referring back to FIG. 12, the liquid treating step S30 and the irradiation step S40 may be performed after the adjustment step S20 is completed. According to an embodiment, the etching step may include a liquid treating step S30 and an irradiation step S40. In the etching step, a specific pattern formed on the substrate M may be etched. For example, the second pattern P2 formed on the substrate M may be etched so that a critical dimension of the first pattern P1 and a critical dimension of the second pattern P2 shown in FIG. 3 and FIG. 4 coincide with each other. The etching step may refer to a critical dimension correction process for correcting a difference between critical dimensions of the first pattern P1 and the second pattern P2.

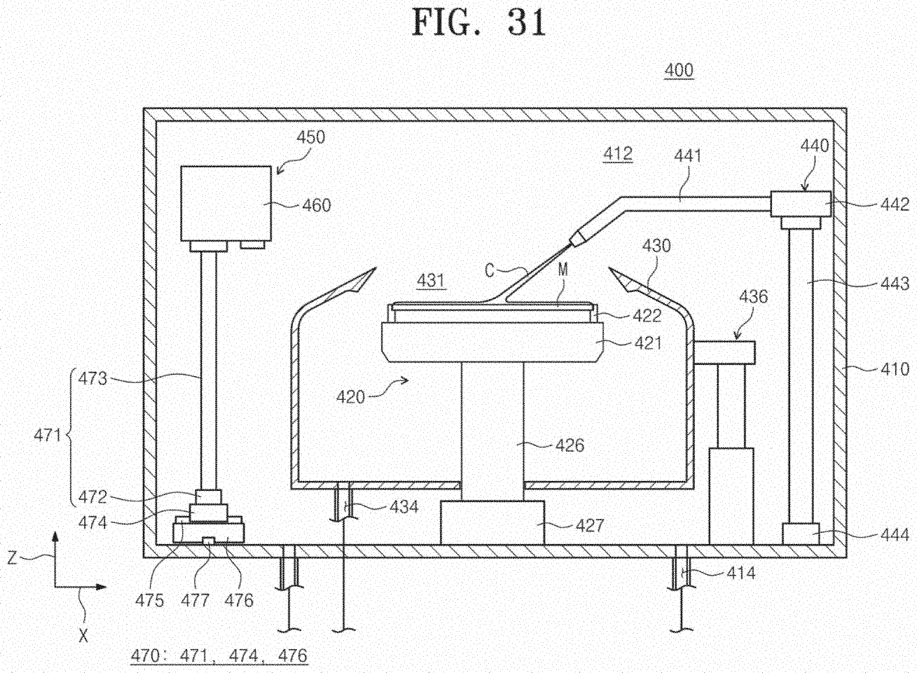

FIG. 31 schematically illustrates a state of a substrate treating apparatus performing the liquid treating step of FIG. 12.

Referring to FIG. 12 and FIG. 31, the liquid treating step S30 may be performed after the adjustment step S20 is completed. In the liquid treatment step S30, the liquid supply unit 440 may be a step of supplying the treating liquid C, which is an etching liquid, to the substrate M supported by the support unit 420.

As shown in FIG. 31, the liquid supply unit 440 moves from a standby position provided with a home port (not shown) to a liquid supply position. For example, the nozzle 441 moves from the standby position to the liquid supply position corresponding to the top side of the substrate. In the liquid treating step S30, the treating liquid C may be supplied to the substrate M at which a rotation is stopped. If the treating liquid C is supplied to the substrate M at which a rotation is stopped, the treating liquid C supplied to the substrate M can be supplied in an amount sufficient to form a puddle. For example, if the treating liquid C is supplied to the substrate M at which a rotation is stopped in the liquid treating step S30, the amount of the supplied treating liquid C may cover an entire top surface of the substrate M, and may not be large even if the treating liquid C flows or does not flow from the substrate M. If necessary, the nozzle 441 may supply the treating liquid C to the entire top surface of the substrate M while changing its position.

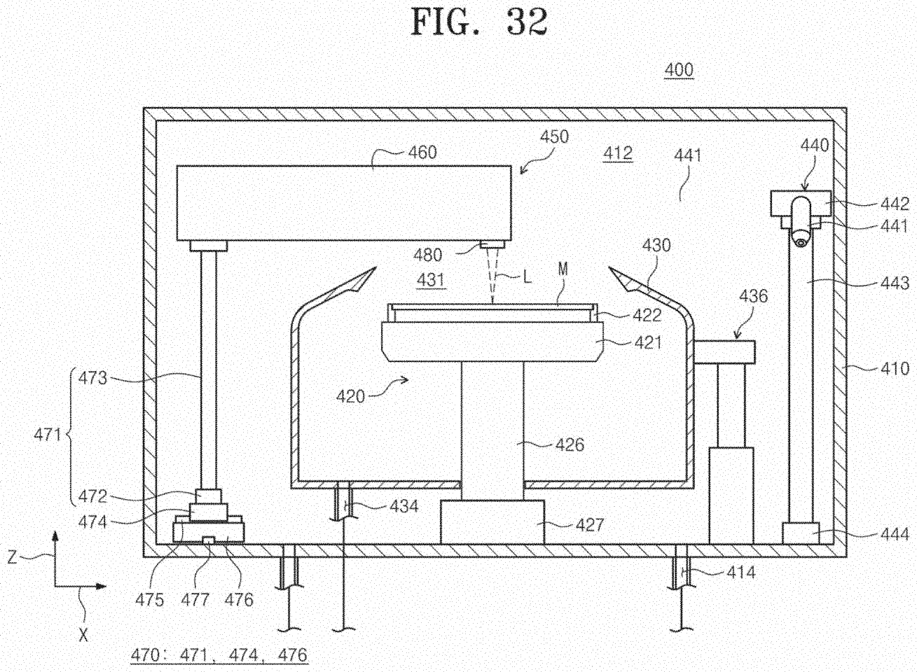

FIG. 32 schematically illustrates a state of the substrate treating apparatus performing the irradiation step of FIG. 12.

Referring to FIG. 6, FIG. 12, and FIG. 32, if the liquid treating step S30 is completed by supplying the treating liquid to the substrate M at which the rotation is stopped, the optical module 450 may move from the standby position to the process position. For example, the optical module 450 may move from the top side of the inspection port 490 illustrated in FIG. 6 to the top side of the substrate M supported by the support unit 420.

The optical module 450 may move by a preset distance in the controller 30. The preset distance in the controller 30 may be a distance from a reference point TP displayed on the grid plate 493 of the first detection member 492 described with reference to FIG. 10 to a specific region of the substrate M supported by the support unit 420. For example, a preset distance in the controller 30 may be a distance from the reference point TP to a center (CP, see FIG. 4) of a specific region at which the second pattern P2 is formed.

The irradiation step S40 is performed if the optical module 450 is positioned on the top side of the substrate M supported by the support unit 420. According to an embodiment, the irradiation step S40 may be performed if the center of the head nozzle 480 is positioned above the center CP (see FIG. 4) of the specific region at which the second pattern P2 of the substrate M is formed.

In the irradiation step S40, the substrate M is heated by irradiating the substrate M with a laser. According to an embodiment, in the irradiation step S40, the substrate M may be heated by irradiating the substrate M with the laser to the second pattern P2 formed in a specific region. For example, the laser irradiated to the second pattern P2 in the irradiation step S40 may have a set condition for collectively irradiating the second patterns P2 by performing the above-described adjustment step S20. In addition, the laser irradiated to the second pattern P2 in the irradiation step S40 may have a set condition for uniformly irradiating the second patterns P2 by performing the above-described adjustment step S20.

A temperature of a specific region in which the second patterns P2 to which the laser is irradiated are formed may increase. The irradiated laser heats the treating liquid previously supplied in a specific region at which the second pattern P2 is formed, and increases an etching rate with respect to the second pattern P2 in the specific region. Accordingly, the critical dimension of the first pattern P1 may be changed from a first width (e.g., 69 nm) to a target critical dimension (e.g., 70 nm). In addition, the critical dimension of the second pattern P2 may be changed from a second width (e.g., 68.5 nm) to a target critical dimension (e.g., 70 nm). That is, in the irradiation step S40, an etching ability of a specific region of the substrate M is improved, and thus a critical dimension deviation of the pattern formed on the substrate M may be minimized.

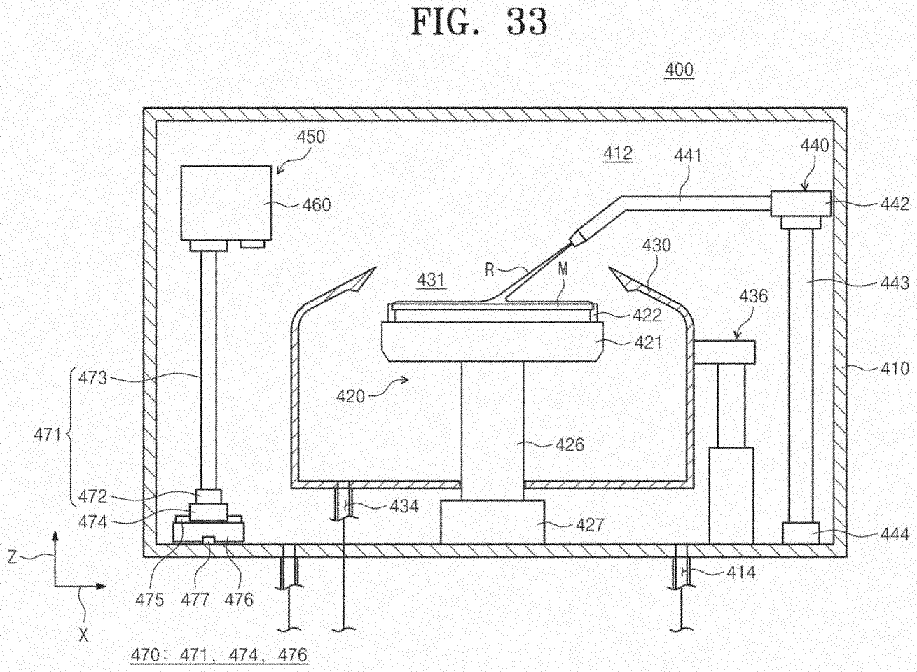

FIG. 33 schematically illustrates a state of the substrate treating apparatus performing the rinsing step of FIG. 12.

Referring to FIG. 12 and FIG. 33, a rinsing step S50 may be performed after the irradiation step S40 is completed. After the irradiation step S40 is completed, the optical module 450 may move from the process position to the standby position. For example, the optical module 450 may move from a top side of the substrate M supported by the support unit 420 to a top side of the inspection port 490 illustrated in FIG. 6. In addition, the liquid supply unit 440 may move from the standby position to the liquid supply position.

In the rinsing step S50, the liquid supply unit 440 may supply the rinsing liquid to a rotating substrate M. In the rinsing step S50, the rinsing liquid may be supplied to the substrate M to remove byproducts attached to the substrate M. In addition, in order to dry the rinsing liquid remaining on the substrate M as is necessary, the support unit 420 can remove the rinsing liquid remaining on the substrate M by rotating the substrate M at a high speed.

Referring back to FIGS. 5 and 12, the substrate M is taken out to the outside of the housing 410 in the substrate taking-out step S60. For example, in the substrate taking-out step S60, the opening (not shown) formed in the housing 410 may be opened by an opening (not shown). The transfer robot 320 shown in FIG. 2 enters the inner space 412 through the opening (not shown) which is open, and the transfer robot 320 may transfer the substrate M from the support unit 420. Before the transfer robot 320 transfers the substrate M from the support unit 420, the lifting/lowering member 436 may downwardly move the treating container 430. If the transfer robot 320 transfers the substrate M from the support unit 420, the lifting/lowering member 436 may upwardly move the treating container 430.

In the above-described embodiment, after the irradiation position adjustment step S22 is performed, it has been described as an example of performing the imaging region adjustment step S24, but is not limited thereto. For example, before the irradiation position adjustment step S22 is performed, the imaging region adjustment step S24 may be performed in advance. In addition, the irradiation position adjustment step S22 and the imaging region adjustment step S24 may be simultaneously performed by the first detection member 492.

In addition, before the irradiation position adjustment step S22 and the adjustment step S24 are performed, the profile adjustment step S26 may be performed. In addition, in the profile adjustment step S26, a profile adjustment step S26 which adjusts the diameter range of the laser, a profile adjustment step S26 which adjusts the steepness range of the laser, and a profile adjustment step S26 which adjusts the uniformity range of the laser may be performed regardless of an order. However, as described above, it is desirable to perform the profile adjustment step S26 of adjusting the diameter range of the laser, and then the profile adjustment step S26 of adjusting the steepness range of the laser.

Hereinafter, a substrate treating method according to another embodiment of the inventive concept will be described. Since the substrate treating method described below is mostly provided to be the same as or similar to the substrate treating method according to an embodiment of the inventive concept described with reference to FIG. 12 to FIG. 33, a description thereof will be omitted.

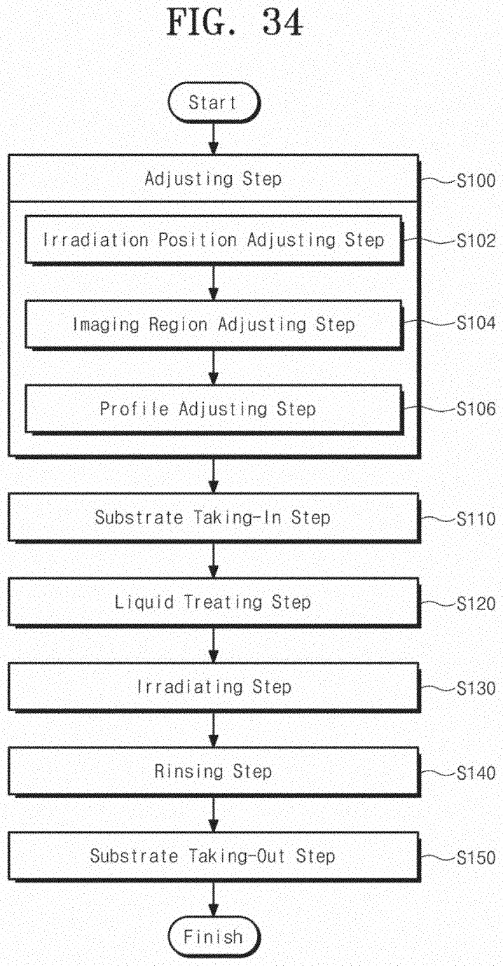

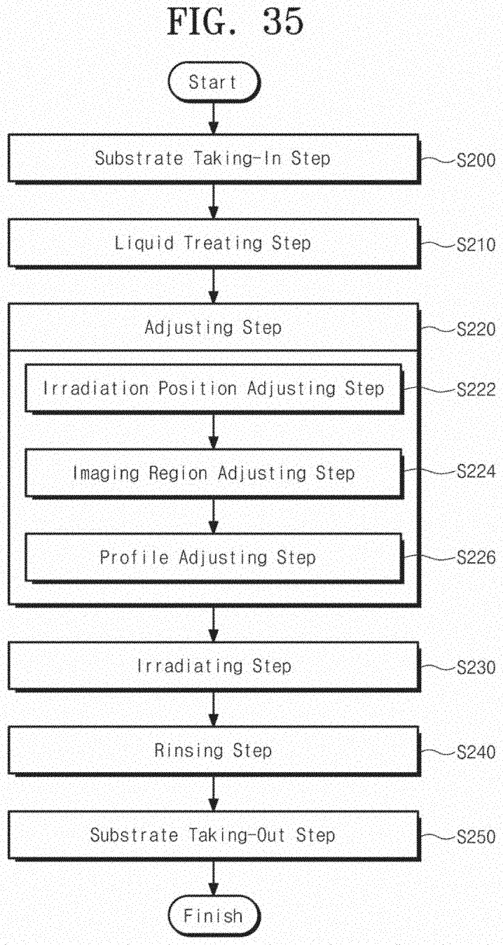

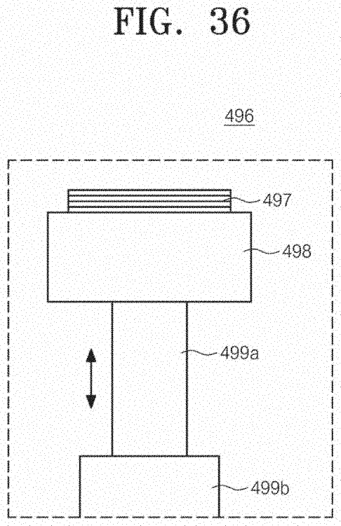

FIG. 34 and FIG. 35 are flowcharts of a substrate treating method according to another embodiment of the inventive concept of FIG. 12.

Referring to FIG. 34, the substrate treating method according to an embodiment of the inventive concept may include an adjustment step S100, a substrate taking-in step S110, a liquid treating step S120, an irradiation step S130, a rinsing step S140, and a substrate taking-out step S150. The adjustment step S100, the substrate taking-in step S110, the liquid treating step S120, the irradiation step S130, the rinsing step S140 and the substrate taking-out step S150 may be sequentially performed. That is, the adjustment step S100 according to an embodiment of the inventive concept may be performed in advance before the substrate is taken into the inner space 412 of FIG. 5.

Referring to FIG. 35, the substrate treating method according to an embodiment of the inventive concept may include the substrate taking-in step S200, the liquid treating step S210, the adjustment step S220, the irradiation step S230, the rinsing step S240, and the substrate taking-out step S250. The substrate taking-in step S200, the liquid treating step S210, the adjustment step S220, the irradiation step S230, the rinsing step S240, and the substrate taking-out step S250 may be sequentially performed. That is, the adjustment step S220 according to an embodiment of the inventive concept may be performed after the liquid treating step S210. Further, the adjustment step S220 according to an embodiment of the inventive concept may be performed between the liquid treating step S210 and the irradiation step S230.

FIG. 36 schematically illustrates a front view of another embodiment of the second detection member according to an embodiment of FIG. 5.

Referring to FIG. 36, the second detection member 496 according to an embodiment of the inventive concept may include an attenuation filter 497, a profiler 498, a profiler frame 499a, and a frame driver 499b. The description of the attenuation filter 497, the profiler 498, and the profiler frame 499a according to an embodiment of the inventive concept have the same or similar structure as the attenuation filter 497, the profiler 498, and the profiler frame 499, respectively, described with reference to FIG. 10 and FIG. 11.

The frame driver 499b is connected to the profiler frame 499a. The frame driver 499b may move the profiler frame 499a. The frame driver 499b may move the profiler frame 499a in the vertical direction. The height of the top end of the attenuation filter 497 may be changed by driving the frame driver 499b.

In each of the profile adjustment step S26 for adjusting the diameter range of the laser described with reference to FIG. 20 to FIG. 28, and the profile adjustment step S26 for adjusting the steepness range of the laser, the head nozzle 480 moves in the vertical direction.

However, since the second detection member 496 according to the embodiment shown in FIG. 36 moves in the vertical direction, the second detection member 496 can move in the vertical direction to adjust the laser diameter and the laser steepness in the profile adjustment step S26, S106, and S226 for adjusting the laser diameter, and the profile adjustment step S26, S106, and S226 for adjusting the laser steepness, respectively. Selectively, both the head nozzle 480 illustrated in FIG. 5 and the second detection member 496 illustrated in FIG. 36 may move in the vertical direction to adjust the laser diameter and the laser steepness.

The effects of the inventive concept are not limited to the above-mentioned effects, and the unmentioned effects can be clearly understood by those skilled in the art to which the inventive concept pertains from the specification and the accompanying drawings.

Although the preferred embodiment of the inventive concept has been illustrated and described until now, the inventive concept is not limited to the above-described specific embodiment, and it is noted that an ordinary person in the art, to which the inventive concept pertains, may be variously carry out the inventive concept without departing from the essence of the inventive concept claimed in the claims and the modifications should not be construed separately from the technical spirit or prospect of the inventive concept.

What is claimed is:

1. A substrate treating method comprising:
treating a substrate by supplying a liquid to the substrate, and irradiating a laser to a region of the substrate on which a specific pattern is formed while the liquid remains on the substrate;
moving an optical module including a laser unit configured to irradiate the laser between a process position for treating the substrate and a standby position deviating from the process position; and
adjusting a state of the optical module at an inspection port provided at the standby position to a set condition before the optical module is moved to the process position.

2. The substrate treating method of claim 1, wherein the standby position includes an outer region of a treating container surrounding a support unit supporting the substrate.

3. The substrate treating method of claim 1, wherein the adjusting the state of the optical module includes an adjusting an irradiation position for adjusting the irradiation position of the laser.

4. The substrate treating method of claim 3, wherein the inspection port includes a first detection member for displaying a reference point and for checking the irradiation position of the laser, and
wherein the adjusting the irradiation position is performed if the laser unit irradiates the laser toward the first detection member and if the irradiation position of the laser irradiated to the first detection member deviates from the reference point.

5. The substrate treating method of claim 4, wherein the adjusting the irradiation position adjusts the irradiation position of the laser irradiated to the first detection member to the reference point by moving the optical module.

6. The substrate treating method of claim 1, wherein the optical module further includes an imaging unit configured to image a region to which the laser is irradiated, and the adjusting the state of the optical module further includes an adjusting an imaging region for aligning the imaging region of the imaging unit with the irradiation position of the laser.

7. The substrate treating method of claim 6, wherein the inspection port includes a first detection member for displaying the reference point and checking the irradiation position of the laser, and
the laser unit irradiates the laser to the first detection member, the imaging unit images the first detection member and acquires an image including the laser irradiated to the first detection member, and
the adjusting the imaging region is performed if the imaging region deviates from the irradiation position of the laser irradiated to the first detection member.

8. The substrate treating method of claim 7, wherein the adjusting the imaging region adjusts a tilting angle of a lens acquired at an imaging path, to adjust a center of the imaging region to a center of the laser irradiated to the reference point.

9. The substrate treating method of claim 1, wherein the adjusting the state of the optical module includes an adjusting a profile for adjusting any one of a diameter of the laser, a steepness of the laser, and a uniformity of the laser, based on a detected profile of the laser, which is detected by detecting the profile of the laser irradiated from the laser unit.

10. The substrate treating method of claim 9, wherein the inspection port includes a second detection member for detecting the profile of the laser, and
the laser unit irradiates the laser to the second detection member, and second detection member detects the profile of the laser which is irradiated, and
the adjusting the profile is performed if the profile detected by the second detection member deviates from a reference range of the profile having the set condition.

11. The substrate treating method of claim 10, wherein the reference range includes a diameter range of the laser, and the optical module moves in a vertical direction to adjust the diameter of the laser, if the profile of the laser detected at the second detection member deviates from the diameter range at the adjusting the profile.

12. The substrate treating method of claim 10, wherein the reference range includes a steepness range of the laser, and
the optical module moves in the vertical direction to adjust a steepness of the laser, if the second detection member deviates from the steepness range of the profile of the laser which is detected by the second detection member at the adjusting the profile.

13. The substrate treating method of claim 10, wherein the reference range includes a uniformity range of the laser, and
an interlock is generated or a position and/or an angle of an optical system which is positioned on a path of the laser irradiated by the laser unit is adjusted, if the second detection member deviates from the uniformity range of the profile of the laser which is detected by the second detection member at the adjusting the profile.

14. The substrate treating method of claim 1, wherein the inspection port includes:
a first detection member displaying a reference point and which checks an irradiation position of the laser; and
a second detection member for detecting a profile of the laser, and
wherein the adjusting the state of the optical module comprises:
adjusting the irradiation position for adjusting the irradiation position of the laser;
adjusting an imaging region for moving the imaging region for imaging the laser to a position at which the laser is irradiated; and
adjusting the profile for adjusting the profile of the laser irradiated from the laser unit to a reference range of the profile having a set condition, based on a detection of the laser unit of the profile of the laser irradiated toward the second detection member, and the profile of the detected laser.

15. A substrate treating method of claim 1, wherein the substrate includes a mask, and
the mask has a first pattern and a second pattern which is different from the first pattern,
the first pattern is formed within a plurality of cells formed at the mask,
the second pattern is formed outside the plurality of cells, and
the specific pattern is the second pattern.

16. The substrate treating method of claim 1, wherein the liquid is supplied to a substrate in which a rotation has stopped, and the laser is irradiated to the substrate in which the rotation is stopped.

17. A substrate treating method comprising:
supplying a treating liquid to a substrate to form a puddle;
irradiating a laser to the substrate to which the treating liquid is supplied;
supplying a rinsing liquid to the substrate; and
adjusting a state of an optical module for irradiating the laser to a set condition, at an inspection port positioned at an outside region of a treating container surrounding a support unit for supporting the substrate, and
wherein the optical module for irradiating the laser at the supplying the treating liquid, the supplying the rinsing liquid, and the adjusting the state of the optical module is positioned at a standby position, and the optical module is positioned at a process position at the irradiating the laser to the substrate, and
wherein the process position is a position at which the substrate corresponds to a top side of the support unit supporting the substrate, the standby position is a position corresponding to a top side of the inspection port.

18. The substrate treating method of claim 17, wherein the liquid treating step supplies the treating liquid to a substrate in which a rotation is stopped,
the irradiating the laser irradiates the laser to the substrate in which the rotation is stopped, and
the supplying a rinsing liquid supplies the rinsing liquid to the substrate in which the rotation is stopped.

19. The substrate treating method of claim 18, wherein the optical module comprises:
a laser unit for irradiating the laser; and
an imaging unit for imaging a region to which the laser is irradiated, and
wherein the inspection port comprises:
a first detection member displaying a reference point and checking an irradiation position of the laser and an imaging region of the imaging unit; and
a second detection member for detecting a profile of the laser, and
wherein the adjusting a state of the optical module comprises:
adjusting an irradiation position for adjusting a center point of the laser which is irradiated to the first detection member to the reference point;
adjusting an imaging region for aligning the imaging region to the center point of the laser which has been adjusted to the reference point; and
adjusting a profile for detecting the profile of the laser which is irradiated toward to the second irradiation member by the laser unit, adjusting the profile of the measured laser to a reference range of the profile having the set condition.

20. The substrate treating method of claim 17, wherein the supplying the treating liquid, the irradiating the laser to the substrate, the supplying the rinsing liquid is performed sequentially, and the adjusting the state of the optical module is performed before the supplying the treating liquid or between the supplying the treating liquid and the irradiating the laser to the substrate.

21.-26. (canceled)
